(19) United States
(12) Patent Application Publication
(10) Pub. No.: US 2026/0321553 A1
(43) Pub. Date: Oct. 15, 2026

(54) SPRING-LOADED SEAL COVER BAND FOR PROTECTING A SUBSTRATE SUPPORT

(71) Applicant: LAM RESEARCH CORPORATION, Fremont, CA (US)

(72) Inventors: Khoa Dang TRUONG, Livermore, CA (US); Behnam BEHZIZ, Newark, CA (US); Roger LIE, San Jose, CA (US); Slobodan MITROVIC, Oakland, CA (US); Yixuan YU, Fremont, CA (US); Darrell EHRLICH, San Jose, CA (US); Feng WANG, Sunnyvale, CA (US); Eric SAMULON, Oakland, CA (US); Andra Yuting CHEN, Dixon, CA (US)

(21) Appl. No.: 19/111,121

(22) PCT Filed: Sep. 15, 2023
(86) PCT No.: PCT/US2023/032885

§ 371 Date: Mar. 12, 2025

Related U.S. Application Data
(60) Provisional application No. 63/407,468, filed on Sep. 16, 2022.
(60) Provisional application No. 63/427,311, filed on Nov. 22, 2022.

(51) Int. Cl. H01J 37/32

(52) U.S. Cl. CPC H01J 37/32715; H01J 37/32697; H01J 2237/334

(57) ABSTRACT

A spring-loaded seal band for protecting a bonding layer of a substrate support, the spring-loaded seal band includes an annular body having a first length when the spring-loaded seal band is in an uncompressed state. The annular body comprises a first annular body portion, an annular arm, and a flexible neck portion that connects the first annular body portion and the annular arm. The spring-loaded seal band is configured to surround the substrate support between a lower surface of a top plate and an upper surface of a baseplate. The lower surface of the top plate and the upper surface of the baseplate is separated by a second length. The first length is greater than the second length. The flexible neck portion is configured to bend when the spring-loaded seal band is in an installed compressed state.

### CROSS-REFERENCE TO RELATED APPLICATIONS

This application claims the benefit of U.S. Provisional Application No. 63/407,468, filed on Sep. 16, 2022, and the benefit of U.S. Provisional Application No. 63/427,311, filed on Nov. 22, 2022. The entire disclosures of each of the applications referenced above are incorporated herein by reference.

### FIELD

The present disclosure relates to substrate processing systems, and more particularly to a spring-loaded seal cover band covering a seal protecting a bond layer between a plate and a baseplate of a substrate support.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. The substrate treatments may include deposition, etching, cleaning, and other treatments. A substrate is arranged on a substrate support in a processing chamber. During processing, gas mixtures may be introduced into the processing chamber using a showerhead or other gas delivery device and plasma may be used to initiate chemical reactions.

The substrate support may include an electrostatic chuck (ESC) including a baseplate, a bonding layer, and a top plate. Substrates are supported on the top plate during plasma processing. The top plate is typically made of ceramic and is attached by the bonding layer to the baseplate. Since the substrate support is arranged in the processing chamber, it is exposed to plasma. Over time, the plasma erodes a radially outer edge of the bonding layer and requires replacement. Typically, the bonding layer fails prior to the lifetime of the ESC and requires downtime for repair/replacement.

### SUMMARY

A substrate support for a substrate processing system includes a baseplate including an upper body portion and a lower body portion. A bonding layer bonds the plate to the baseplate. A seal includes a first annular body arranged around the upper body portion of the baseplate and a radially outer edge of the bonding layer and between a lower surface of the plate and an upper surface of the lower body portion of the baseplate. A spring-loaded seal cover band includes a second annular body. The spring-loaded seal cover band is arranged around the seal between the lower surface of the plate and the upper surface of the lower body portion of the baseplate. The spring-loaded seal cover band has a first length that is greater than a second length defined between the lower surface of the plate and the upper surface of the lower body portion of the baseplate. A portion of the spring-loaded seal cover band is configured to bend when installed to bias the spring-loaded seal cover band against the upper surface of the lower body portion of the baseplate and the lower surface of the plate.

In other features, the second annular body includes a material selected from a group consisting of perfluoroalkoxy alkanes (PFA) and polytetrafluoroethylene (PTFE). The first length is in a predetermined range between 1.02 times the second length and 1.2 times the second length. The second annular body includes a first body portion, a neck, and an annular arm extending from the first body portion. The neck is located between the annular arm and the first body portion.

In other features, the annular arm extends from the first body portion at a predetermined angle in range from 105° to 165°. The annular arm extends from the first body portion at a predetermined angle in range from 125° to 155°. The annular arm has a length in a range from 5% to 50% of the first length. The annular arm has a length in a range from 5% to 30% of the first length. The spring-loaded seal cover band includes an annular inner member and an outer layer arranged on the annular inner member, and wherein the outer layer comprises a plasma-resistant material. The annular inner member includes spring metal. The outer layer is selected from a group consisting of perfluoroalkoxy alkanes (PFA), polytetrafluoroethylene (PTFE), and ceramic.

In other features, the first body portion is arranged above the annular arm. The annular arm extends radially outwardly when installed around the seal. The first body portion is arranged below the annular arm. The annular arm extends radially inwardly when installed around the seal.

In other features, the first body portion is arranged below the annular arm. The annular arm extends radially outwardly when installed around the seal. The second annular body includes a middle body portion, a first annular arm extending from a first end of the middle body portion, and a second annular arm extending from a second end of the middle body portion.

In other features, the first annular arm and the second annular arm extend radially outwardly when installed around the seal. The first annular arm and the second annular arm extend radially inwardly when installed around the seal. The second annular body includes a first body portion, a first annular arm extending radially outwardly from a first end of the first body portion, and a second annular arm extending radially inwardly from the first end of the first body portion.

In other features, the second annular body includes a first body portion, a second body portion, and a “V”-shaped portion arranged between the first body portion and the second body portion.

In other features, a cavity of the “V”-shaped faces one of radially outwardly when installed around the seal and radially inwardly when installed around the seal.

In other features, the second annular body includes a first body portion, a second body portion, a third body portion, a first “V”-shaped portion arranged between the first body portion and the second body portion, and a second “V”-shaped portion arranged between the first body portion and the second body portion.

In other features, a seal-facing surface of the first body portion is “V”-shaped. A seal-facing surface of the first body portion is “D”-shaped. The second annular body includes a first body portion, an annular arm extending from the first body portion, and a “V”-shaped cavity located on a radially outer surface of the first body portion between the first body portion and the annular arm.

In other features, a middle of the “V”-shaped cavity is located in a range from 5% to 50% of a length of the spring-loaded seal cover band. A middle of the “V”-shaped cavity is located in a range from 5% to 30% of an axial length of the spring-loaded seal cover band.

In other features, sides of the “V”-shaped cavity form first and second predetermined angles relative to a middle of the “V”-shaped cavity, wherein the first and second predetermined angles are in a range from 25° to 55°. The first predetermined angle is different than the second predetermined angle.

A substrate support for a substrate processing system includes a baseplate including an upper body portion and a lower body portion, a plate, a bonding layer to bond the plate to the baseplate, and a spring-loaded seal band including a second annular body. The spring-loaded seal band is arranged around the baseplate between a lower surface of the plate and an upper surface of the lower body portion of the baseplate. The spring-loaded seal band has first length that is greater than a second length defined between the upper surface of the lower body portion of the baseplate and the lower surface of the plate. A portion of the spring-loaded seal band bends when installed to bias the spring-loaded seal band against the upper surface of the lower body portion of the baseplate and the lower surface of the plate.

A spring-loaded seal band for protecting a bonding layer of a substrate support, the spring-loaded seal band includes an annular body having a first length when the spring-loaded seal band is in an uncompressed state. The annular body comprises a first annular body portion, an annular arm, and a flexible neck portion that connects the first annular body portion and the annular arm. The spring-loaded seal band is configured to surround the substrate support between a lower surface of a top plate and an upper surface of a baseplate, the lower surface of the top plate and the upper surface of the baseplate is separated by a second length. The first length is greater than the second length. The flexible neck portion is configured to bend when the spring-loaded seal band is in an installed compressed state and biased against the upper surface of the baseplate and the lower surface of the top plate, and the first length is reduced when the spring-loaded seal band is in the installed compressed state.

In other features, the annular body includes a material selected from a group consisting of perfluoroalkoxy alkanes (PFA) and polytetrafluoroethylene (PTFE). The first length is 1.02 times to 1.2 times greater than the second length when in the uncompressed state. The annular arm extends from the first annular body portion at an angle in range from 105° to 165° when in the uncompressed state. The annular arm extends from the first annular body portion at an angle from 125° to 155° when uncompressed. The annular arm has a length in a range from 5% to 50% of the first length. The annular arm has a length in a range from 5% to 30% of the first length.

In other features, the spring-loaded seal band includes an annular inner member and an outer layer on the annular inner member. The outer layer comprises a plasma-resistant material.

In other features, the annular inner member includes spring metal. The outer layer is selected from a group consisting of perfluoroalkoxy alkanes (PFA), polytetrafluoroethylene (PTFE), and ceramic. A seal-facing surface of the first annular body portion has a shape selected from a group consisting of “V”-shaped and “D”-shaped. The angle decreases in a range from 1° to 25° when in the installed compressed state. The angle decreases in a range from 3° to 15° when in the installed compressed state.

A spring-loaded seal band for protecting a bonding layer a substrate support includes an annular body having a first length when the spring-loaded seal band is in an uncompressed state. The annular body comprises a first annular body portion, an annular arm, and a “V”-shaped cavity between the first annular body portion and the annular arm. The spring-loaded seal band is configured to surround the substrate support between a lower surface of a plate and an upper surface of a baseplate, the lower surface of the plate and the upper surface of the baseplate is separated by a second length. The first length is greater than a second length. At least one of the first annular body portion and the annular arm of the spring-loaded seal band is configured to bend when in an installed compressed state to bias the spring-loaded seal band against the upper surface of the baseplate and the lower surface of the plate and the first length is reduced when the spring-loaded seal band is in the installed compressed state.

In other features, the annular body includes a material selected from a group consisting of perfluoroalkoxy alkanes (PFA) and polytetrafluoroethylene (PTFE). The first length is in a predetermined range from 1.02 to 1.2 times the second length. A middle of the “V”-shaped cavity is located in a range from 5% to 50% of a length of the spring-loaded seal band. A middle of the “V”-shaped cavity is located in a range from 5% to 30% of a length of the spring-loaded seal band. Sides of the “V”-shaped cavity form a first angle and a second angle relative to a middle of the “V”-shaped cavity, wherein the first angle and the second angle are in a range from 25° to 55°. The annular arm has a length in a range from 5% to 50% of the first length. The annular arm has a length in a range from 5% to 30% of the first length.

In other features, the spring-loaded seal band includes an annular inner member and an outer layer on the annular inner member. The outer layer comprises a plasma-resistant material. The annular inner member includes spring metal. The outer layer is selected from a group consisting of perfluoroalkoxy alkanes (PFA), polytetrafluoroethylene (PTFE), and ceramic.

In other features, a seal-facing surface of the first annular body portion has a shape selected from a group consisting of “V”-shaped and “D”-shaped. A sum of the first angle and the second angle decreases in a range from 1° to 25° when in the installed compressed state. A sum of the first angle and the second angle decreases in a range from 3° to 15° when in the installed compressed state.

A substrate support for a substrate processing system includes a baseplate including an upper body portion and a lower body portion, a plate, a bonding layer to bond the plate to the baseplate, a spring-loaded seal including a first annular body arranged around the upper body portion of the baseplate and a radially outer edge of the bonding layer and between a lower surface of the plate and an upper surface of the lower body portion of the baseplate, and a seal cover band including a second annular body. The seal cover band is arranged around the spring-loaded seal between the lower surface of the plate and the upper surface of the lower body portion of the baseplate, the spring-loaded seal includes a first spring configured to bend when installed to bias a first arm of the spring-loaded seal against the lower surface of the plate, and a second spring configured to bend when installed to bias a second arm of the spring-loaded seal against the upper surface of the lower body portion of the baseplate.

In other features, the spring-loaded seal has a first length that is greater than a second length defined between the lower surface of the plate and the upper surface of the lower body portion of the baseplate. In other features, the seal cover band includes a material selected from a group consisting of perfluoroalkoxy alkanes (PFA) and polytetrafluoroethylene (PTFE).

In other features, the first spring has a length in a range from 5% to 40% of the first length, and the second spring has a length in a range from 5% to 40% of the first length. In other features, the first annular body has a length in a range from 10% to 80% of the first length.

In other features, the first arm includes a surface having a length in a range from 5% to 40% of the first length, and the second arm includes a surface having a length in a range from 5% to 40% of the first length. In other features the first annular body has a first thickness, the first spring has a thickness in a range of 10% to 90% of the first thickness, and the second spring has a thickness in a range of 10% to 90% of the first thickness.

In other features, the seal cover band includes a first protrusion defined between the second annular body and a first extension of the seal cover band, the first protrusion adjacent the first spring of the spring-loaded seal when installed, and a second protrusion defined between the second annular body and a second extension of the seal cover band, the second protrusion adjacent the second spring of the spring-loaded seal when installed.

A substrate support for a substrate processing system includes a baseplate including an upper body portion and a lower body portion, a plate, a bonding layer to bond the plate to the baseplate, and a spring-loaded seal including an annular body arranged around the upper body portion of the baseplate and a radially outer edge of the bonding layer and between a lower surface of the plate and an upper surface of the lower body portion of the baseplate. The spring-loaded seal includes a curved arm extending from a bottom surface of the annular body, the curved arm configured to bend when installed to bias an upper surface of the spring-loaded seal against the lower surface of the plate.

In other features, the spring-loaded seal has a first length that is greater than a second length defined between the lower surface of the plate and the upper surface of the lower body portion of the baseplate. In other features, the spring-loaded seal includes a material selected from a group consisting of perfluoroalkoxy alkanes (PFA) and polytetrafluoroethylene (PTFE).

In other features, a height of the annular body is in a range from 10% to 90% of the first length. In other features, the annular body has a first width, and a width of the curved arm is in a range from 5% to 50% of the first width. In other features, the curved arm has a curvature of at least ninety degrees.

A substrate support for a substrate processing system includes a baseplate including an upper body portion and a lower body portion, a plate, a bonding layer to bond the plate to the baseplate, a spring-loaded seal including an annular body arranged around the upper body portion of the baseplate and a radially outer edge of the bonding layer and between a lower surface of the plate and an upper surface of the lower body portion of the baseplate, and an O-ring seal. The spring-loaded seal includes an arm extending from a lower surface of the annular body to define a pocket region between the arm, the lower surface of the annular body, the upper surface of the lower body portion of the baseplate, and a radially outer surface of the upper body portion of the baseplate, the O-ring seal is within the pocket region, and the arm of the spring-loaded seal is configured to bend when installed to bias an upper surface of the annular body against the lower surface of the plate.

In other features, the spring-loaded seal has a first length that is greater than a second length defined between the lower surface of the plate and the upper surface of the lower body portion of the baseplate. In other features, the spring-loaded seal includes a material selected from a group consisting of perfluoroalkoxy alkanes (PFA) and polytetrafluoroethylene (PTFE).

In other features, the arm of the spring-loaded seal has a length in a range of 50% to 95% of a diameter of the O-ring seal. In other features, the annular body has a first width, and the diameter of the O-ring seal is less than or equal to 125% of the first width.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a substrate processing system comprising a substrate support including a baseplate, a plate, a bonding layer, a seal, and a seal cover band according to the present disclosure;

FIG. 2 is a partial, enlarged side cross-sectional view of an example of a baseplate, a bonding layer, a plate, a seal, and a seal cover band according to the present disclosure;

FIGS. 3-6 are partial, enlarged side cross-sectional views of other examples of a baseplate, a bonding layer, a plate, a seal, and a seal cover band according to the present disclosure;

FIG. 7A is partial, enlarged side cross-sectional views of another example of a baseplate, a bonding layer, a plate, a seal, and a seal cover band according to the present disclosure;

FIG. 7B is a top view of the seal and seal cover band illustrated in FIG. 7A;

FIG. 7C is a side cross-sectional view of the seal and seal cover band taken at A-A in FIG. 7B;

FIGS. 8-9 are partial, enlarged side cross-sectional views of other examples of a baseplate, a bonding layer, a plate, a seal, and a seal cover band according to the present disclosure;

FIG. 10A is a side cross-sectional view of another example of a seal cover band according to the present disclosure;

FIG. 10B is a partial, enlarged side cross-sectional view of a baseplate, a bonding layer, a plate, an O-ring seal, and a seal cover band according to the present disclosure;

FIG. 11A is a partial, enlarged side cross-sectional view of an example of a baseplate, a bonding layer, a plate, a seal, and an annular spring-loaded seal cover band according to the present disclosure;

FIG. 11B is a side cross-sectional view of the annular spring-loaded seal cover band of FIG. 11A;

FIG. 12-18 are partial, enlarged side cross-sectional views of other examples of a baseplate, a bonding layer, a plate, a seal, and/or an annular spring-loaded seal cover band according to the present disclosure;

FIG. 19A is a side cross-sectional view of the annular spring-loaded seal cover band with an annular arm according to the present disclosure;

FIGS. 19B and 19C are partial, enlarged side cross-sectional views of another example of a baseplate, a bonding layer, a plate, a seal, and the annular spring-loaded seal cover band of FIG. 19A in partially installed and installed positions, respectively;

FIG. 19D is a top view of the seal and annular spring-loaded seal cover band of FIGS. 19B and 19C;

FIG. 19E is a side cross-sectional view of the seal and annular spring-loaded seal cover band taken at B-B in FIG. 19D;

FIG. 20A is a side cross-sectional view of the annular spring-loaded seal cover band with a cavity according to the present disclosure;

FIGS. 20B and 20C are a partial, enlarged side cross-sectional view of another example of a baseplate, a bonding layer, a plate, a seal, and the annular spring-loaded seal cover band of FIG. 20A in partially installed and installed positions, respectively;

FIG. 21A is a side cross-sectional view of the annular spring-loaded seal cover band with an annular arm according to the present disclosure;

FIGS. 21B and 21C are a partial, enlarged side cross-sectional view of another example of a baseplate, a bonding layer, a plate, a seal, and the annular spring-loaded seal cover band of FIG. 21A in partially installed and installed positions, respectively;

FIG. 22 is a side cross-sectional view of an annular spring-loaded seal cover band including an inner member made of spring metal and an outer coating according to the present disclosure;

FIGS. 23 and 24 are partial, enlarged side cross-sectional views of other examples of a baseplate, a bonding layer, a plate, a seal, and/or an annular spring-loaded seal cover band according to the present disclosure;

FIG. 25A is a side cross-sectional view of an annular spring-loaded seal with two annular spring portions according to the present disclosure;

FIG. 25B is a side cross-sectional view of an annular seal cover band for contacting the annular spring-loaded seal of FIG. 25A;

FIG. 25C is a partial, enlarged side cross-sectional view of another example of a baseplate, a bonding layer, a plate, and the annular spring-loaded seal of FIG. 25A and the annular seal cover band of FIG. 25B in installed positions;

FIG. 25D is a top view of the annular spring-loaded seal and seal cover band of FIGS. 25A-25C;

FIG. 25E is a side cross-sectional view of the annular spring-loaded seal and seal cover band taken at C-C in FIG. 25D;

FIG. 26A is a side cross-sectional view of an annular spring-loaded seal including an annular spring arm according to the present disclosure;

FIG. 26B is a partial, enlarged side cross-sectional view of another example of a baseplate, a bonding layer, a plate, and the annular spring-loaded seal of FIG. 26A in an installed position;

FIG. 26C is a top view of the annular spring-loaded seal of FIGS. 26A and 26B;

FIG. 26D is a side cross-sectional view of the annular spring-loaded seal taken at D-D in FIG. 26C;

FIG. 27A is a partial, enlarged side cross-sectional view of another example of a baseplate, a bonding layer, a plate, an annular spring-loaded seal and an elastomer, according to the present disclosure;

FIG. 27B is a top view of the annular spring-loaded seal and of FIG. 27A; and FIG. 27C is a side cross-sectional view of the annular spring-loaded seal taken at E-E in FIG. 27B.

In the drawings, reference numbers may be reused to identify similar and/or identical elements.

### DETAILED DESCRIPTION

A substrate support such as an electrostatic chuck (ESC) includes a baseplate and a plate arranged on top of the baseplate. A bonding layer bonds the plate to an upper surface of the baseplate. In addition to mechanically connecting the plate to the baseplate, the bonding layer also provides a vacuum seal and a temperature break between the plate and the baseplate. Unless protected, a radially outer edge of the bonding layer is exposed to plasma and is prone to plasma erosion. Failure of the bonding layer in this way limits the lifetime to less than 100 RF hours.

Seals have been used to protect the radially outer edge of the bonding layer. The seals are made of plasma-resistant materials and are arranged around the radially outer edge of the bonding layer. In some examples, the seals are made from an elastomer such as fluoroelastomer polymer (hereinafter elastomer seals or E-seals). Examples of elastomers include fluoroelastomer polymer such as perfluoroelastomer (FFKM) or fluorocarbon-based fluoroelastomer (FKM), although other plasma resistant materials can be used.

While the lifetime of the elastomer seal (E-seal) is shorter than the ESC lifetime, the E-seal is field replaceable at a relatively low cost. The E-seal provides a seal against the plate (e.g., a ceramic plate) and the baseplate to protect the radially outer edge of the bonding layer during plasma processing.

Trade-offs are made when seals are designed. For example, seals with larger radial thicknesses provide improved protection of the bonding layer but have a higher cracking risk. Seals with smaller radial thicknesses have a shorter lifetime and require more frequent replacement. This tradeoff will become more difficult when increased RF power levels are used in next generation tools.

The present disclosure relates to a seal cover band that is arranged around the seal to protect the seal and to various seal/seal cover band assemblies. The seal cover band protects and mechanically supports the seal at the radially outer edge of the substrate support. The seal cover band improves the plasma resistance of the seals. This, in turn, leads to longer mean time between cleaning (MTBC) and lower replacement frequency. The seal cover band provides mechanical support to the seal, which relaxes dimensional constrains (e.g., aspect ratio or height divided by radial thickness) of the seal, and allows the use of edge ring materials that reduce arcing risk.

The seal cover band de-couples the functions of edge bond protection and plasma resistance. The seal provides sealing and bonding layer protection, and the seal cover band protects the seal from plasma exposure. As a result, the seal can be made with softer materials that provide a more effective seal against the plate and the baseplate without excessive compression force against the plate (which may correspond to a thin ceramic plate). The seal cover band can be retrofitted on existing substrate supports with seals without changing the substrate support or seal design.

In other examples, an O-ring seal is used to protect the radially outer edge of the bonding layer and the seal cover band is configured to protect the O-ring seal.

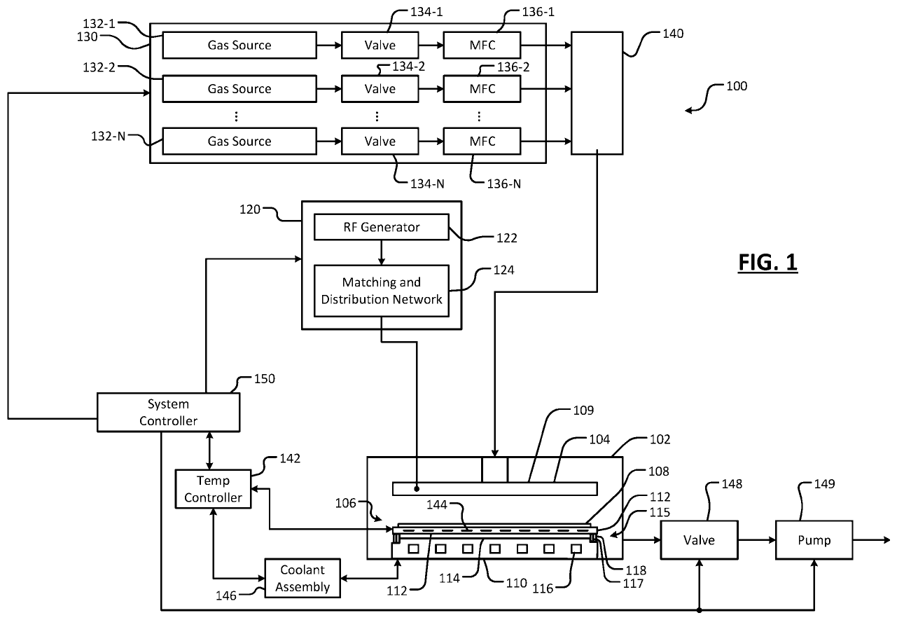

Referring now to FIG. 1, an example of a substrate processing system 100 for performing treatment such as etching using RF plasma is shown. While etching is shown, the seal cover band can be used on substrate supports for other types of plasma-assisted substrate treatment. The substrate processing system 100 includes a processing chamber 102 that encloses other components of the substrate processing system 100 and contains the RF plasma. The substrate processing system 100 includes an upper electrode 104 and a substrate support 106, such as an electrostatic chuck (ESC). During operation, a substrate 108 is arranged on the substrate support 106.

For example only, the upper electrode 104 may include a showerhead 109 that introduces and distributes process gases within the processing chamber 102. The showerhead 109 may include a stem portion including one end connected to a top surface of the processing chamber. A base portion is generally cylindrical and extends radially outwardly from an opposite end of the stem portion at a location that is spaced from the top surface of the processing chamber. A substrate-facing surface or faceplate of the base portion of the showerhead includes a plurality of holes through which process gas or purge gas flows. Alternately, the upper electrode 104 may include a conducting plate and the process gases may be introduced in another manner.

The substrate support 106 may comprise an electrostatic chuck (ESC) that includes a baseplate 110 that is conductive and acts as a lower electrode. A plate 112 is arranged on the baseplate 110. The plate 112 may correspond to a ceramic multi-zone heating plate. A bonding layer 114 attaches the plate 112 to the baseplate 110 to provide a mechanical connection, a vacuum seal, and/or a thermal break. The baseplate 110 may include one or more channels 116 for flowing fluid such as coolant.

As will be described further below, a seal/seal cover band assembly 115 according to the present disclosure includes a seal 117 is arranged around the baseplate 110 between the plate 112 and a radially projecting lower portion of the baseplate 110. The seal 117 protects the bonding layer 114. The seal/seal cover band assembly 115 further includes a seal cover band 118 arranged around the seal 117 to protect the seal 117 from the effects of the plasma and/or other chemistry.

An RF generating system 120 generates and outputs an RF voltage to one of the upper electrode 104 and the lower electrode (e.g., the baseplate 110 of the substrate support 106). The other one of the upper electrode 104 and the baseplate 110 may be DC grounded, AC grounded or floating. For example only, the RF generating system 120 may include an RF voltage generator 122 that generates the RF voltage that is fed by a matching and distribution network 124 to the upper electrode 104 or the baseplate 110. In other examples, the plasma may be generated inductively or remotely. While the RF generating system 120 corresponds to a capacitively coupled plasma (CCP) system, the principles of the present disclosure may also be implemented in other plasma processing systems, such as a transformer coupled plasma (TCP) system, an inductively coupled plasma (ICP) system, or other types of plasma processing systems.

A gas delivery system 130 includes one or more gas sources 132-1, 132-2, . . . , and 132-N (collectively gas sources 132), where N is an integer greater than zero. The gas sources 132 supply one or more precursors, etching gases, carrier gases, purge gases, and mixtures thereof to the processing chamber 102. Vaporized precursor may also be used. The gas sources 132 are connected by valves 134-1, 134-2, . . . , and 134-N (collectively valves 134) and mass flow controllers 136-1, 136-2, . . . , and 136-N (collectively mass flow controllers 136) to a manifold 140. An output of the manifold 140 is connected to the gas delivery device in the processing chamber 102.

A temperature controller 142 may be connected to a plurality of heating elements 144 (e.g., thermal control elements, or TCEs) arranged in the plate 112. For example, the heating elements 144 may include, but are not limited to, macro heating elements corresponding to respective zones in a multi-zone heating plate and/or an array of micro heating elements disposed across multiple zones of a multi-zone heating plate. The plate 112 may also include one or more conductors (not shown) to engage and release the substrate 108 using electrostatic force. The temperature controller 142 may be used to adjust output of the plurality of heating elements 144 to control a temperature of the substrate support 106 and the substrate 108. The temperature controller 142 may also communicate with a coolant assembly 146 to control coolant flow through the channels 116. For example, the coolant assembly 146 may include a coolant pump and reservoir. The temperature controller 142 operates the coolant assembly 146 to selectively flow the coolant through the channels 116 to cool the substrate support 106.

A valve 148 and pump 149 may be used to control pressure and to evacuate reactants from the processing chamber 102. A system controller 150 may be used to control components of the substrate processing system 100. Although shown as separate controllers, the temperature controller 142 may be implemented by the system controller 150.

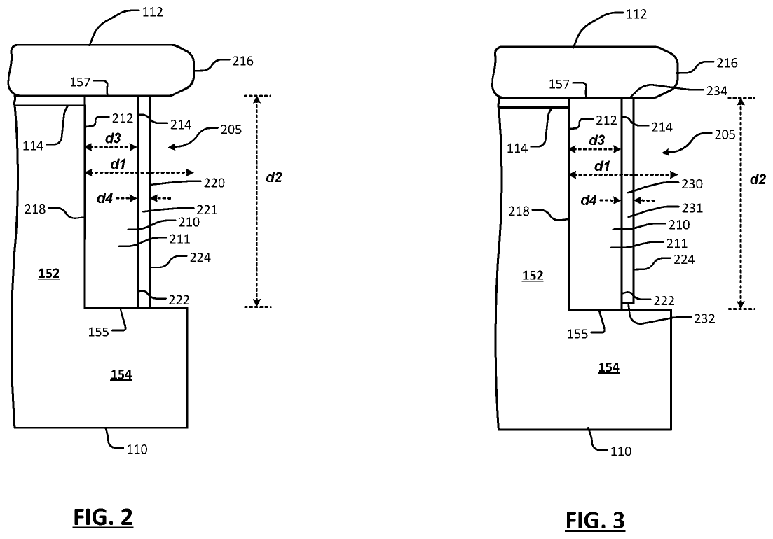

Referring now to FIG. 2, the baseplate 110 includes an upper body portion 152 and a lower body portion 154. The upper body portion 152 has a cylindrical shape and a first radius. The lower body portion 154 of the baseplate 110 is also cylindrical and has a second radius that is greater than the first radius of the upper body portion 152.

In FIG. 2, a radially outer edge 216 of the plate 112 extends outwardly relative to the upper body portion 152 of the baseplate 110 approximately the same distance (e.g., distance d1) that the lower body portion 154 extends. However, the radially outer edge 216 of the plate 112 can extend from the upper body portion 152 less than or greater than the distance that the lower body portion 154 extends relative to the upper body portion 152. A distance d2 is defined between a lower horizontal surface 157 of the plate 112 and an upper horizontal surface 155 of the lower body portion 154. The bonding layer 114 is arranged between the plate 112 and the baseplate 110.

A seal/seal cover band assembly 205 includes a seal 210 including an annular body 211 that is arranged around a radially outer surface of the bonding layer 114 against a radially outer surface 218 of the upper body portion 152 of the baseplate 110 and the lower horizontal surface 157 of the plate 112. In some examples, the seal 210 is made of elastomer, although other materials can be used. In some examples, the seal 210 is slightly compressed between the lower horizontal surface 157 of the plate 112 and the upper horizontal surface 155 of the lower body portion 154 of the baseplate 110. Additional examples of the seal 210 can be found in commonly assigned U.S. Pat. No. 9,868,392, entitled “Edge Seal for Lower Electrode Assembly”, issued on Jan. 16, 2018, which is hereby incorporated herein by reference in its entirety.

In some examples, a distance d3 (corresponding to a radial thickness of the seal 210) is defined between a radially inner surface 212 of the seal 210 and a radially outer surface 214 of the seal 210. In some examples, the distance d3 is less than the distance d1.

The seal/seal cover band assembly 205 further includes a seal cover band 220 including an annular body 221 that is arranged adjacent to and in contact with the radially outer surface 214 of the seal 210. In some examples, a radial thickness of the seal cover band 220 (between a radially inner surface 222 and a radially outer surface 224 thereof) is equal to a distance d4. In some examples, the distance d4 is in a range from 10 to 100 mil, although other thicknesses can be used. In some examples, the distance d4 is in a range from 10 to 50 mil, although other thicknesses can be used. In some examples, the distance d4 is in a range from 10 to 20 mil, although other thicknesses can be used.

In some examples, the distance d3 is in a first predetermined range from 60% to 80% of the distance d1. In some examples, the distance d4 is in a second predetermined range from 15% to 40% of the distance d1. In some examples, a height of the seal cover band 220 is in a range from 95% to 105% of the distance d2, when not compressed. In some examples, a height of the seal cover band 220 is in a range from 98% to 102% of the distance d2, when not compressed. In some examples, a height of the seal cover band 220 is in a range from 99% to 101% of the distance d2, when not compressed.

In some examples, the seal cover band 220 is made of a material that can be stretched around the radially outer edge 216 of the plate 112 during installation. In some examples, the seal cover band 220 is made of a material that resists plasma erosion and/or exposure to other chemistry that is used in the processing chamber 102. In some examples, the seal cover band 220 is made of a material selected from a group consisting of perfluoroalkoxy alkanes (PFA) and polytetrafluoroethylene (PTFE). In some examples, the seal cover band 220 is milled or cast. In some examples, the seal cover band includes greater than 60%, 70%, 80%, or 90% PFA. In some examples, the seal cover band includes greater than 60%, 70%, 80%, or 90% PTFE.

Referring now to FIGS. 3-9, additional examples of the seal/seal cover band assembly 205 are shown. Different seal/seal cover band assemblies have different physical arrangements between the seal and seal cover band. In FIG. 3, a lower edge 232 of a seal cover band 230 (including an annular body 231) is spaced from the upper horizontal surface 155 of the lower body portion 154 of the baseplate 110. An upper edge 234 of the seal cover band 230 is in contact with the lower horizontal surface 157 of the plate 112.

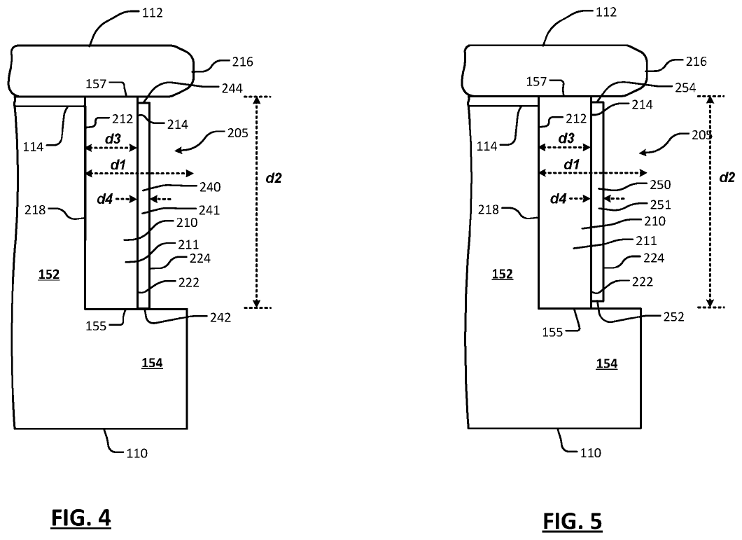

In FIG. 4, a lower edge 242 of a seal cover band 240 (including an annular body 241) is in contact with the upper horizontal surface 155 of the lower body portion 154 of the baseplate 110. An upper edge 244 of the seal cover band 240 is spaced from the lower horizontal surface 157 of the plate 112.

In FIG. 5, a lower edge 252 of a seal cover band 250 (including an annular body 251) is spaced from the upper horizontal surface 155 of the lower body portion 154 of the baseplate 110. An upper edge 254 of the seal cover band 250 is spaced from the lower horizontal surface 157 of the plate 112.

In some examples, providing a gap at one or both sides may help when attempting to remove and replace the seal cover band.

In the examples shown in FIGS. 3 to 5, the radially inner surface 212 and the radially outer surface 214 of the seals 210 are substantially parallel to an axial direction. Likewise, the radially inner surface 222 and the radially outer surface 224 of the seal cover bands 220, 230, 240 and 250 are substantially parallel to an axial direction. As used in this context, substantially parallel means that the surfaces are within +/−3° of parallel. In some examples, both the seal and seal cover band apply radially inward compression, when assembled for operation, to maintain their respective position relative to the baseplate.

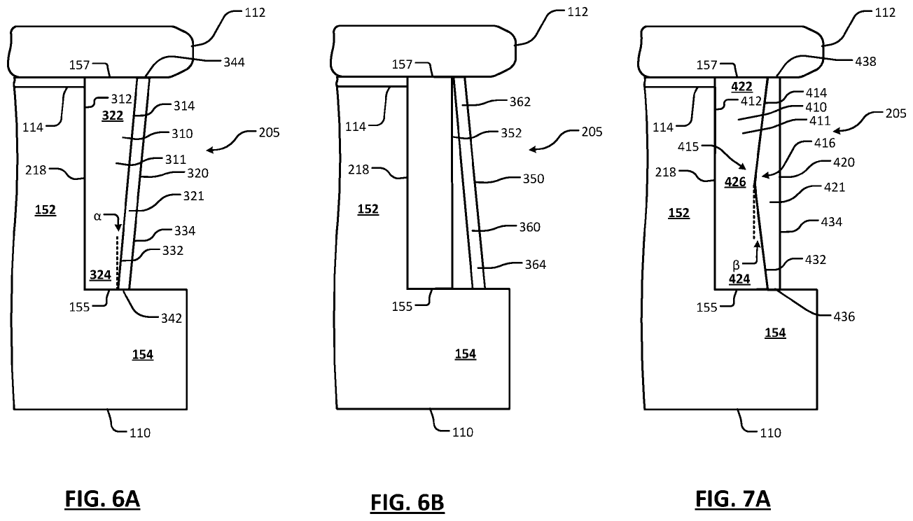

In FIG. 6A, a seal 310 includes an annular body 311 and a seal cover band 320 arranged around the seal 310 includes an annular body 321. The seal 310 includes a radially inner surface 312 that extends axially and a radially outer surface 314 that is sloped relative to the axial direction. The seal cover band 320 includes a radially inner surface 332 which is sloped relative to the axial direction and radially outer surface 334 that is sloped (or extends axially and/or has another profile). The radially outer surface 314 of the seal 310, the radially inner surface 332 of the seal cover band 320, and/or the radially outer surface 334 of the seal cover band 320 are sloped at an angle α relative to the axial direction. In some examples, α is greater than 0° and less than 15°. In other examples, α is greater than 0° and less than 10°. In other examples, α is greater than zero and less than 5°.

In some examples, a first body portion 322 of the seal 310 arranged adjacent to the plate 112 is wider than a second body portion 324 of the seal 310 arranged adjacent to the lower body portion 154 of the baseplate 110. The wider first body portion 322 provides more protection to the bond layer and the narrower second body portion 324 reduces the overall material cost while still providing sufficient friction to keep the seal 310 in place. In some examples, the outer surface 314 of the seal 310 slopes continuously from the first body portion 322 to the second body portion 324. In other examples, a width of the seal 310 monotonically decreases from a location near the plate 112 to a location near the lower body portion 154 of the baseplate 110. In some examples, the outer surface 314 of the seal 310 is stair-stepped from the first body portion 322 to the second body portion 324.

In some examples, the radially inner surface 332 and/or the radially outer surface 334 of the seal cover band 320 have a continuous slope (adjacent to the first body portion 322 to the second body portion 324) and are substantially parallel to one another. In some examples, a distance between the radially outer surface 218 of the upper body portion 152 and the radially inner surface 332 of the seal cover band 320 continuously or monotonically decreases from a location near the plate 112 to a location near the lower body portion 154 of the baseplate 110. In some examples, the radially inner surface 332 and the radially outer surface 334 of the seal cover band 320 are mating surfaces that are stair stepped.

In FIG. 6A, the seal cover band 320 extends fully between the lower horizontal surface 157 of the plate 112 and the upper horizontal surface 155 of the lower body portion 154 of the baseplate 110. As can be appreciated, one or both edges 342 and 344 of the seal cover band 320 can be spaced in a similar manner shown in FIGS. 3 to 5. As can be appreciated, the seal 310 and the seal cover band 320 provide additional compressive force and/or material to protect the radially outer edge of the bonding layer 114, which increases MTBC.

In FIG. 6B, a seal cover band 350 is arranged around a seal 352. The seal cover band 350 includes an annular body 360 including a first body portion 362 with a smaller inner and/or outer radius than a lower body portion 364 of the annular body 360. In some examples, a radial thickness is uniform in an axial direction. In other examples, the radial thickness varies in an axial direction. The seal cover band 350 has a length in an axial direction that is greater than the distance d2 between the lower surface of the plate 112 and the upper surface of the lower body portion 154 of the baseplate 110. A radially inner surface of the seal cover band 350 and a radially outer surface of the seal 352 may be complementary as shown in FIG. 6A or not complementary as shown in FIG. 6B.

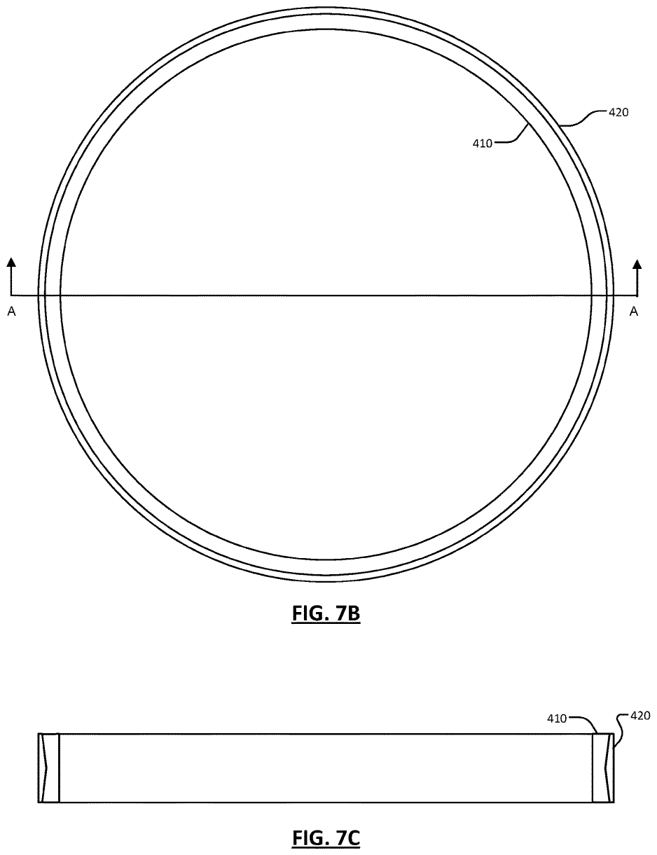

In FIG. 7A, a seal 410 (with an annular body 411) and a seal cover band 420 (with an annular body 421) include mating positioning surfaces 415 and 416, respectively. The mating positioning surfaces 415 and 416 help to initially position the seal cover band 420 and maintain relative positions of the seal cover band 420, the seal 410, the plate 112, and the lower body portion 154 of the baseplate 110.

For example, the mating positioning surface 415 comprises a cavity formed in a radially outer surface 414 of the annular body 411. A radially inner surface 412 of the annular body 411 extends axially. The mating positioning surface 416 comprises a projection on a radially inner surface 432 of the annular body 421. When installing the seal cover band 420 over the seal 410, the mating positioning surfaces 415 and 416 assist with the proper positioning of the seal cover band 420 relative to the seal 410. In other words, as the seal cover band 420 is installed over the plate 112 and the upper edge of the seal cover band 420 clears a bottom edge of the plate, the mating positioning surface 416 is aligned with and engages the mating positioning surface 415. The mating positioning surfaces 415 and 416 resist further movement of the seal cover band 420 relative to the seal 410.

A radially outer surface 434 of the annular body 421 extends axially, although other profiles can be used. In some examples, the cavity is “V”-shaped, and the projection is “V”-shaped, although other shapes can be used. As can be appreciated, the cavity can be located on the seal cover band 420 and the projection can be located on the seal 410.

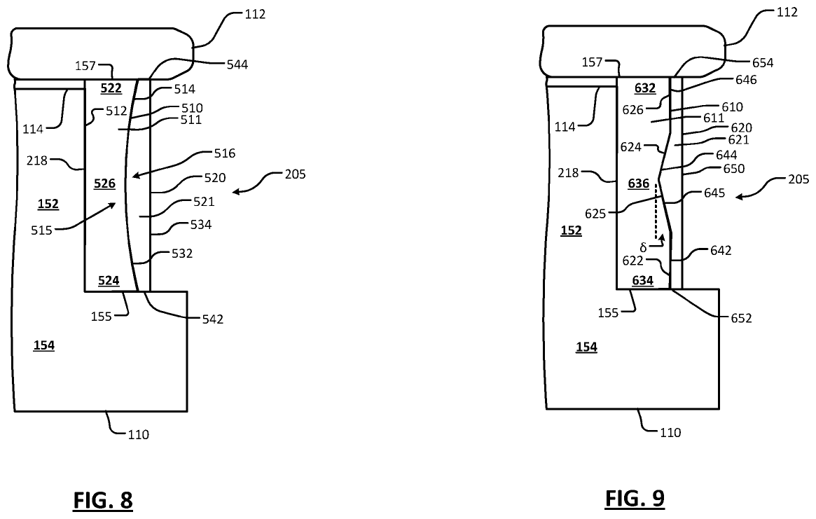

In some examples, a first portion 422 of the seal 410 arranged adjacent to the plate 112 and a second portion 424 of the seal 410 arranged adjacent to the lower body portion 154 of the baseplate 110 are wider than a third portion 426 of the seal 410 located there between. In some examples, the outer surface 414 of the seal 410 slopes inwardly continuously, monotonically, or in steps from the first portion 422 to the third portion 426 and from the second portion 424 to the third portion 426. While the radially inner surface 432 of the seal cover band 420 includes first and second linear segments, one or more curved surfaces can be used as shown in FIG. 8.

The radially outer surface 414 of the seal 410 and the radially inner surface 432 of the seal cover band 420 are sloped at an angle @ relative to the axial direction. In some examples, ß is greater than 0° and less than 15°. In other examples, ß is greater than 0° and less than 10°. In other examples, B is greater than zero and less than 5°.

In FIG. 7A, the seal cover band 420 extends fully between the plate 112 and the lower body portion 154 of the baseplate 110. As can be appreciated, one or both edges 436 and 438 of the seal cover band 420 can be spaced in a similar manner shown in FIGS. 3 to 5.

FIG. 7B is a top view of the seal 410 and seal cover band 420 illustrated in FIG. 7A. As shown in FIG. 7B, the seal 410 and the seal cover band 420 may each have a generally circular shape. Diameters of the seal 410 and the seal cover band 420 may correspond to one another. For example, an inner diameter of the seal cover band 420 may correspond to an outer diameter of the seal 410.

An inner diameter of the seal 410 may correspond to, for example, the radially outer surface 218 of the upper body portion 152 of the baseplate 110. In some example embodiments, the inner diameter of the seal 410 may be slightly smaller than the diameter of the radially outer surface 218, to allow the seal 410 to be stretched around the upper body portion 152 to remain in place.

The inner diameter of the seal cover band 420 may be slightly smaller than the outer diameter of the seal 410, to allow the seal cover band 420 to be stretched around the seal 410 to remain in place. FIG. 7C is a side cross-sectional view of the seal 410 and seal cover band 420, taken at A-A in FIG. 7B.

In FIG. 8, a seal 510 (with an annular body 511) and a seal cover band 520 (with an annular body 521), respectively, are shown. The seal 510 and the seal cover band 520 include mating positioning surfaces 515 and 516, respectively. The seal 510 includes a first portion 522, a second portion 524, and a third portion 526. In some examples, a width of the seal 510 decreases continuously, monotonically, or in steps from the first portion 522 near the plate 112 to the third portion 526. In some examples, a width of the seal 510 decreases continuously, monotonically, or in steps from the second portion 524 near the lower body portion 154 to the third portion 526.

For example, a radially inner surface 512 of the seal 510 extends axially and a radially outer surface 514 of the seal 510 is fully or partially arcuate to define a cavity (or a projection). A radially inner surface 532 of the seal cover band 520 is fully or partially arcuate to define and a projection (or a cavity) that is received by the cavity of the seal 510. In some examples, a radially outer surface 534 of the seal cover band 520 extends axially, although other profiles can be used.

In FIG. 8, the seal cover band 520 extends fully between the plate 112 and the lower body portion 154 of the baseplate 110. As can be appreciated, one or both edges 542 and 544 of the seal cover band 520 can be spaced in a similar manner shown in FIGS. 3 to 5.

In FIG. 9, a seal 610 (with an annular body 611) and a seal cover band 620 (with an annular body 621) are shown. The seal 610 includes surfaces 622 and 626 that extend in an axial direction from a location near the plate 112 and from a location near the lower body portion 154 of the baseplate, respectively. The seal 610 further includes surfaces 624 and 625 that extend between the surfaces 622 and 626 and that are sloped or curved.

In some examples, a first portion 632 of the seal 610 arranged adjacent to and below the plate 112 and a second portion 634 of the seal 610 arranged adjacent to and above the lower body portion 154 of the baseplate 110 are wider in a radial direction than a third portion 636 of the seal 610 located there between (e.g., near a meeting point of the surfaces 624 and 625 and/or a middle of the seal 610). While the surfaces 624 and 625 of the seal cover band 620 are shown as generally linear, one or more curved surfaces can be used.

The seal cover band 620 includes surfaces 642 and 646 that extend in an axial direction from a location adjacent to and below the plate 112 and a location adjacent to and below the lower body portion 154 of the baseplate 110, respectively. The seal cover band 620 further includes surfaces 644 and 645 extending between the surfaces 642 and 646 and that are sloped or curved. An outer surface 650 of the seal cover band 620 can extend in an axial direction, although other profiles can be used.

In FIG. 9, the seal cover band 620 extends fully between the plate 112 and the lower body portion 154 of the baseplate 110. As can be appreciated, one or both edges 652 and 654 of the seal cover band 620 can be spaced in a similar manner shown in FIGS. 3 to 5.

The seal 610 and the seal cover band 620 include abutting surfaces (622 and 642, 625 and 645, 624 and 644, and 626 and 646). The surfaces 622 and 642 and 626 and 646 are sloped at an angle o relative to the axial direction. In some examples, δ is greater than zero and less than 15°. In other examples, δ is greater than zero and less than 10°. In other examples, δ is greater than zero and less than 5°. While the abutting surfaces 622 and 642, 625 and 645, 624 and 644, and 626 and 646 are shown as linear segments, one or more curved segments can be used.

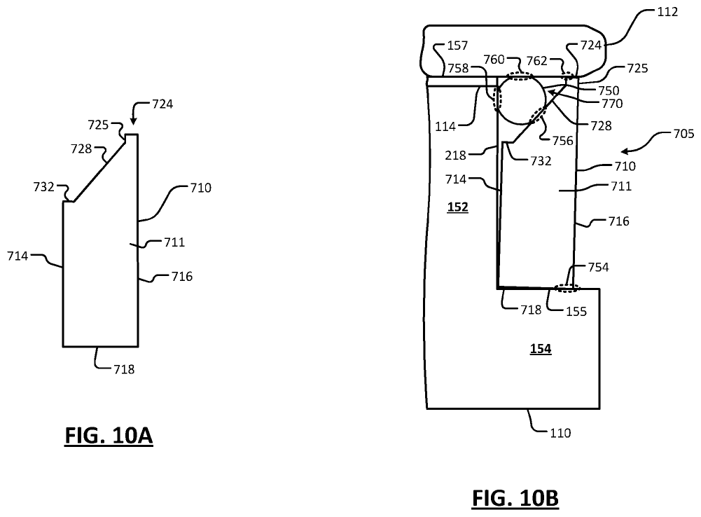

Referring now to FIGS. 10A and 10B, a seal cover band 710 that can be used with an O-ring seal (FIG. 10B) is shown. The seal cover band 710 includes an annular body 711, a radially inner surface 714, a radially outer surface 716, a lower surface 718, and an upper surface 724. A projection 725 is arranged between the upper surface 724 and one end of a sloped surface 728. A lower projection 732 is arranged between an opposite end of the sloped surface 728 and the radially inner surface 714. In some examples, the sloped surface 728 extends to the radially inner surface 714 and the projection 732 is omitted. If used, the lower projection helps to define a pocket region 770 (FIG. 10B) and/or provides mechanical stiffness to the seal.

In FIG. 10B, an O-ring/seal cover band assembly 705 includes an O-ring seal 750 that is arranged between the lower horizontal surface 157 of the plate 112, the radially outer surface 218 of the upper body portion 152 of the baseplate 110, and the sloped surface 728 of the seal cover band 710. The seal/seal cover band assembly 705 further includes the seal cover band 710 that forms annular seals at sealing locations 754, 756, 758, 760 and 762. The sealing location 754 is located between the lower surface 718 of the seal cover band 710 and the upper horizontal surface 155 of the lower body portion 154. The sealing location 756 is located between the sloped surface 728 of the seal cover band 710 and the O-ring seal 750.

The sealing location 758 is located between the radially outer surface 218 of the upper body portion 152 and the O-ring seal 750. The sealing location 760 is located between the lower horizontal surface 157 of the plate 112 and the O-ring seal 750. The seal location 762 is located between the lower horizontal surface 157 of the plate 112 and the projection 725 of the seal cover band 710. In some examples, the seal cover band 710 is rotated slightly clockwise when installed to apply pressure on the sealing locations 754, 756, 758, 760 and 762. In some examples, the sealing locations 758, 760 provide a vacuum seal and the remaining seal locations 754, 756, and 762 provide redundant seals that protect the bonding layer 114 and the O-ring seal 750. In some examples, the O-ring seal 750 may be made of or include an outer coating of PFA or PTFE.

The sloped surface 728, the projection 725, and/or the projection 732 (if used) define a pocket region 770 around the seal. The pocked region is sized to allow enough room for the O-ring seal 750 to be located therein and to bias the O-ring seal 750 inwardly. In other words, the seal restricts movement of the O-ring seal 750. The projection 725 and the upper surface 724 are sufficiently rigid to provide a sealing surface that is parallel to and biased against the lower horizontal surface of the plate 112 and to reduce the likelihood of plasma making it past the seal and entering the pocket region 770. The projection 725 has a radial thickness that is sufficiently wide to provide mechanical stiffness and support required for the seal to contact and seal both of the seal locations 762 and 754, which reduces the likelihood of plasma entering the pocket region 770.

With additional protection provided by the seal cover band, the lifetime of the seal can be prolonged so that failure of the seal does not control MTBC for applications such as conductor etch (CE). Instead of replacing the seal at every MTBC period, the seal can be used for several MTBC periods in many dielectric etch (DE) applications where erosion of the seal is minimal. This change leads to a reduction in cost and an increase in tool productivity.

The seal cover band also provides additional mechanical support to seals made of softer materials and mitigates buckling risk. This allows the use of seals with higher aspect ratios (corresponding to a height of the seal divided by a thickness of the seal). Higher aspect ratio seals are required for ESCs used in some applications such as next generation DE.

Lower compressive force can be applied individually by the seal and the seal cover band since the compressive force of the seal and the seal cover band are partially or fully added. As a result, ceramic warpage and bond delamination risks are much lower with the seal and the seal cover band according to the present disclosure.

In other features, the present disclosure relates to annular spring-loaded seal bands and annular spring-loaded seal cover bands as will be described further below. The annular spring-loaded seal cover bands can be used in conjunction with seals as described above. Alternately, annular spring-loaded seal bands can be used with or without the seals due to the improved plasma seal and are referred to herein more generally as annular spring-loaded seal bands.

The annular spring-loaded seal bands are compressed between the lower surface of the upper plate and the upper surface of the lower body portion of the baseplate. In some examples, the annular spring-loaded seal band includes an annular body, an annular arm extending from the annular body at an angle, and a neck arranged between the annular body and the annular arm. Spring force is created when the annular spring-loaded seal bands are installed and bend at the neck and/or at the arm. The spring force biases opposite ends of the annular spring-loaded seal bands against the lower surface of the upper plate and the upper surface of the lower body portion of the baseplate to create a plasma seal. In some examples, the annular arm bends in a direction towards the annular body but does not touch the annular body when installed.

In some examples, the annular spring-loaded seal band includes an annular body with a “V”-shaped annular cavity arranged vertically along a radially outer surface of the annular body. In some examples, the “V”-shaped annular cavity is arranged closer to a first end of the spring-loaded cover band that is distal from a second end of the spring-loaded cover band arranged adjacent to the lower surface of the upper plate when installed. Arranging the annular arm and/or the “V”-shaped annular cavity closer to the baseplate side helps to minimize spring pressure variations closer to the bonding layer, which is a primary structure to be protected from plasma erosion.

The annular spring-loaded seal band is configured to bend at the neck, annular arm and/or the “V”-shaped annular cavity to provide spring force that biases the annular spring-loaded seal band against the lower surface of the upper plate and the upper surface of the lower body portion of the baseplate. In some examples, the seal blocks plasma (the seal may or may not provide a hermetic seal). As can be appreciated, if not enough spring force is supplied, the spring-loaded seal cover band may not create a seal to block plasma and premature erosion of the seal and/or bonding layer may occur. If too much spring force is supplied, the spring-loaded seal cover band may cause delamination of the upper plate from the baseplate at the bond layer. In some examples, the spring-loaded cover band provides sufficient force to provide a plasma seal and less than or equal to ⅓ of a delamination pressure required to delaminate upper plate from the baseplate at the bonding layer. In some examples, an axial height of the spring-loaded seal cover band is in a range from 3/16″ to 1″, although larger or smaller vertical heights can be used. As can be appreciated, obtaining the desired amount of spring force with a small axial thickness can be challenging.

While some deformation is desired, too much deformation and/or plastic deformation is less desirable. The annular spring-loaded seal band is exposed to on-off cycling of heat, plasma, and/or chemistry. Therefore, a balance is struck between spring force, deformation and/or plastic deformation to ensure longevity of the spring-loaded seal cover band and the bonding layer.

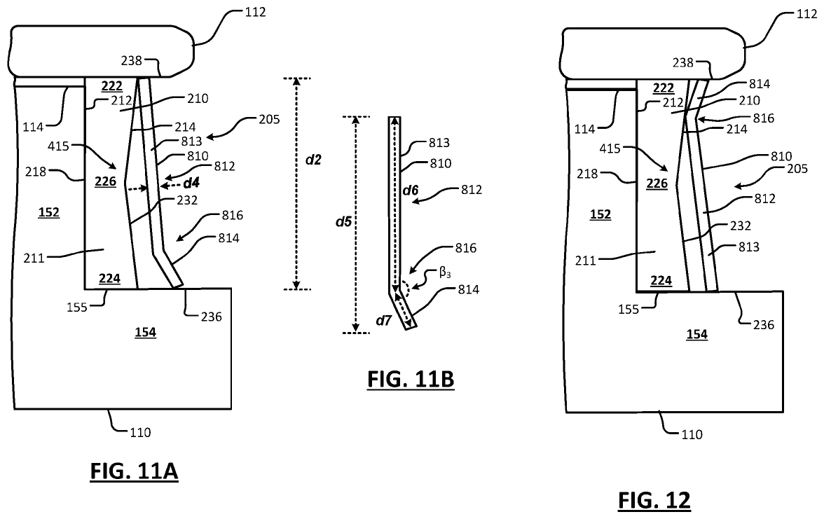

Referring now to FIGS. 11A to 13, an annular spring-loaded seal band 810 is shown. In FIGS. 11A and 11B, the annular spring-loaded seal band 810 is configured to bend or deform when installed and to bias opposite ends thereof against the surface 238 of the upper plate 112 and the surface 236 of the baseplate 110, respectively, to form a plasma seal. The annular spring-loaded seal band 810 includes an annular body 812 including a first body portion 813 and an annular arm 814 extending at an angle β₃ from the first body portion 813. A neck 816 is located between the first body portion 813 and the annular arm 814.

The annular spring-loaded seal band 810 is configured to bend at the neck 816 and/or the annular arm 814 when installed such that spring force is applied in first and second opposing directions against the surface 238 of the upper plate 112 and the surface 236 of the baseplate 110, respectively. The spring force is selected to be sufficient to block plasma without causing delamination.

In some examples, the annular spring-loaded seal band 810 has an overall length d5 when not compressed, the first body portion 813 has a length d6, and the annular arm 814 has a length d7. In some examples, the length d5 is greater than the length d2 (between the lower surface 238 of the upper plate 112 and the upper surface 236 of the baseplate 110). In some examples, d5 is in a range from 102% of d2 to 120% of d2. In some examples, β₃ is in a range from 105° to 165°. In some examples, β₃ is in a range from 125° to 155°. In some examples, β₃ decreases in a range from 1° to 25° when in the installed compressed state. In some examples, β₃ decreases in a range from 3° to 15° when in the installed compressed state.

In some examples, the length d7 of the annular arm 814 is in a range from 5%*d5 to 50%*d5. In some examples, the length d7 of the annular arm 814 is in a range from 5%*d5 to 30%*d5. In some examples, the annular spring-loaded seal band 810 is at least partially deformed at the neck 816 and at the annular arm 814 without significant plastic deformation when installed.

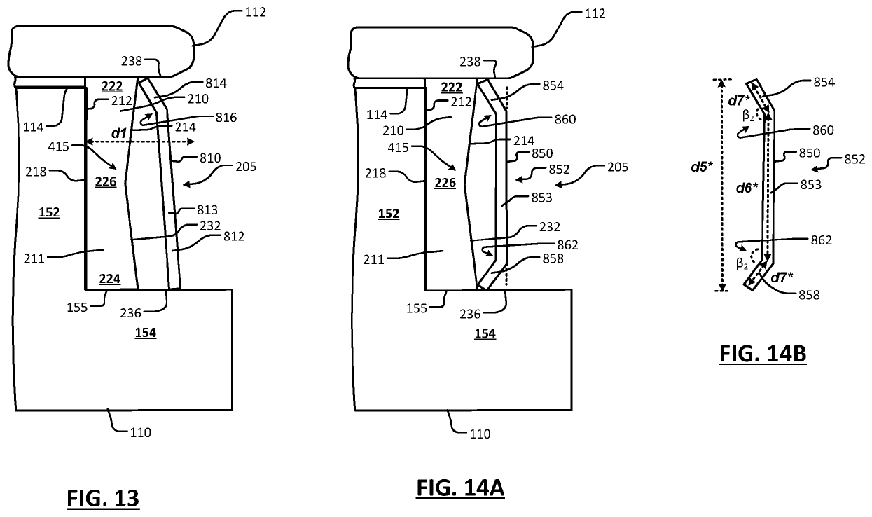

The annular spring-loaded seal band 810 can be installed in different orientations. In FIG. 11A, the annular arm 814 is arranged below the first body portion 813 and the annular arm 814 extends in a radially outward direction from the first body portion 813. In FIG. 12, the annular arm 814 is arranged above the first body portion 813 and the annular arm 814 extends in a radially outward direction from the first body portion 813. In some embodiments, the inner diameter surface of the annular spring-loaded seal band 810 has a contour or shape that mates with or is complementary to a radially outer contour or shape of the seal 210. In FIG. 13, the annular arm 814 is arranged above the annular body 812 and the annular arm 814 extends in a radially inward direction from the first body portion 813 towards the seal 210.

Referring now to FIG. 14A-18, additional examples of annular spring-loaded seal bands are shown. In FIGS. 14A and 14B, an annular spring-loaded seal band 850 is shown. The annular spring-loaded seal band 850 includes an annular body 852 including a middle body portion 853 arranged between first and second annular arms 854 and 858. The first and second annular arms 854 and 858 extend at an angle β₂ from the middle body portion 853 and define necks 860 and 862 between the middle body portion 853 and the first and second annular arms 854 and 858, respectively. The annular spring-loaded seal band 850 is configured to bend during installation such that spring force is applied in first and second opposite directions against the lower surface 238 of the upper plate 112 and the upper surface 236 of the baseplate 110.

In some examples, the annular spring-loaded seal band 850 has an overall length d5* when not compressed, the middle body portion 853 has a length d6* and the first and second annular arms 854 and 858 have a length d7*. In some examples, the length d5* is greater than the length d2* between the lower surface 238 of the upper plate 112 and the upper surface 236 of the baseplate 110. In some examples, d5* is in a range from 102% of d2 to 120% of d2.

In some examples, the angle β₂ is in a range from 105° to 165°. In some examples, the angle β₂ is in a range from 125° to 155°. In some examples, β₂ decreases in a range from 1° to 25° when in the installed compressed state. In some examples, β₂ decreases in a range from 3° to 15° when in the installed compressed state.

In the example in FIGS. 14A and 14B, the first and second annular arms 854 and 858 are configured with the same angle. However, the first and second annular arms 854 and 858 can extend from the middle body portion 853 at different angles. In some examples, the length d7* of the first and second annular arms 854 and 858 is in a range from 5%*d5* to 30%*d5*. In some examples, the length d7* of the first and second annular arms 854 and 858 is in a range from 5%*d5* to 20%*d5*. In some examples, the length d6* of the middle body portion 853 is in a range from 10%*d5* to 40%*d5*. In some examples, the annular spring-loaded seal band 850 bends at one or both of the necks 860 and 862 and/or at one or both of the first and second annular arms 854 and 858 when installed without significant plastic deformation. Too much plastic deformation may prevent the spring-loaded seal cover band from creating a plasma seal when installed or after use. Very high plastic deformation may also cause the annular spring-loaded seal band to fail/crack around the neck area and thus reduce the seal band's useful life.

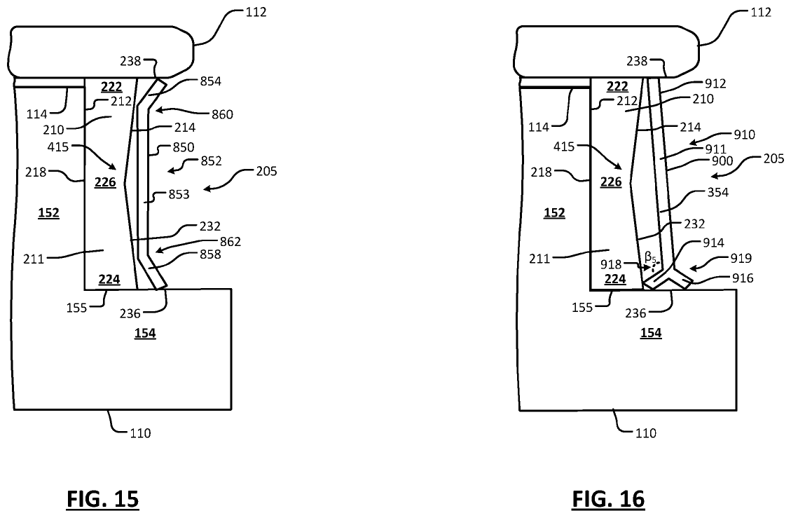

The annular spring-loaded seal band 810 can be installed in different orientations. In FIG. 14A, the first and second annular arms 854 and 858 extend radially inwardly from the middle body portion 853. In FIG. 15, the first and second annular arms 854 and 858 extend radially outwardly from the middle body portion 853. In some embodiments, the inner diameter surface of the annular spring-loaded seal band 810 in FIG. 15 has a contour or shape that mates with or is complementary to a radially outer contour or shape of the seal 210.

In FIG. 16, an annular spring-loaded seal band 900 is shown. The annular spring-loaded seal band 900 includes an annular body 911 with a first body portion 912 and first and second annular arms 914 and 916 extending in opposite directions at an angle β₅ (or different angles β₅ β_{5′} and (5) from one end of the first body portion 912. The first and second annular arms 914 and 916 define neck portions 918 and 919 between the first body portion 912 and the first and second annular arms 914 and 916, respectively. The first and second annular arms 914 and 916 and/or the neck portions 918 and 919 of the annular spring-loaded seal band 900 are configured to bend and deform during installation such that force is applied in first and second opposite directions against the lower surface 238 of the upper plate 112 and the upper surface 236 of the baseplate 110.

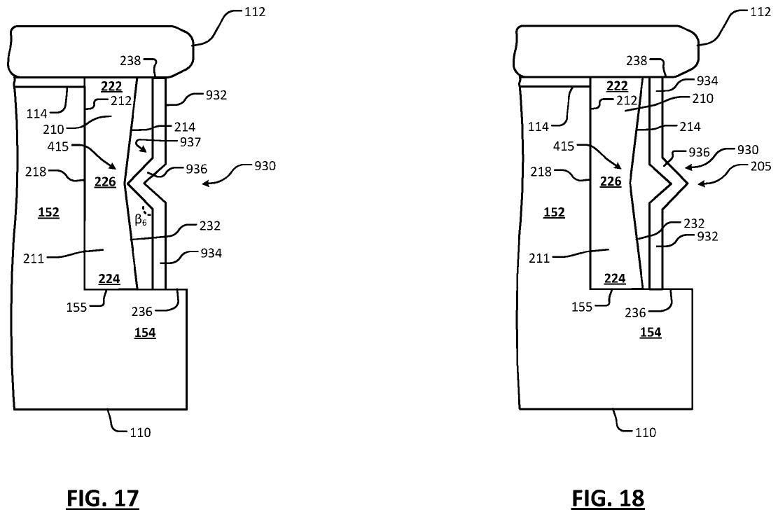

In FIGS. 17 and 18, another example of an annular spring-loaded seal band 930 is shown. The annular spring-loaded seal band 930 includes an annular body with first and second body portions 932 and 934 and a “V”-shaped annular body portion 936 connected between the first and second body portions 932 and 934. In some examples, first and second body portions 932 and 934 extend in a parallel direction and/or along the same line when in an uncompressed state. The “V”-shaped annular body portion 936 forms an angle β₆ (or different angles β₆ and β_{6′}) at neck portions 937 located between the “V”-shaped annular body portion 936 and the first and second body portions 932 and 934. The annular spring-loaded seal band 930 is configured to bend during installation such that sufficient spring force is applied in first and second opposing directions against the lower surface 238 of the upper plate 112 and the upper surface 236 of the baseplate 110.

The annular spring-loaded seal band 930 can be installed in different orientations. In FIG. 17, a cavity of the “V”-shaped annular body portion 936 faces radially outwardly. In FIG. 18, a cavity of the “V”-shaped annular body portion 936 faces radially inwardly. In some embodiments, the inner diameter surface of the annular spring-loaded seal band 930 in FIG. 17 has a contour or shape that mates with or is complementary to a radially outer contour or shape of the seal 210.

In some examples, the angle β₆ (or different angles β₆ and β₆) are in a range from 105° to 165°. In some examples, the angle β₆ (or different angles β₆ and B 6′) are in a range from 125° to 155°. In some examples, β₆ and/or β_{6′} decrease in a range from 1° to 25° when in the installed compressed state. In some examples, β₆ and/or β_{6′} decrease in a range from 3° to 15° when in the installed compressed state.

In some examples, the legs of the “V”-shaped annular body portion 936 are in a range from 5% to 20% of the length of the annular spring-loaded seal band 930.

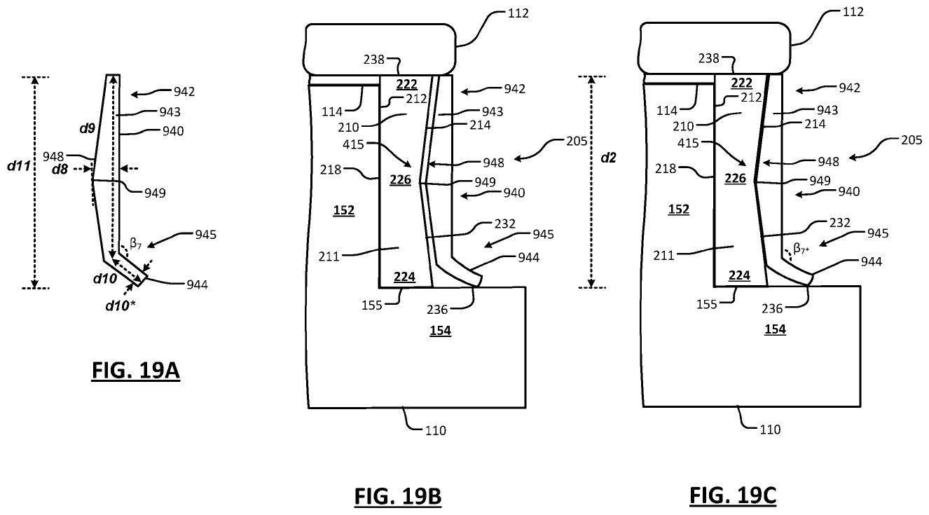

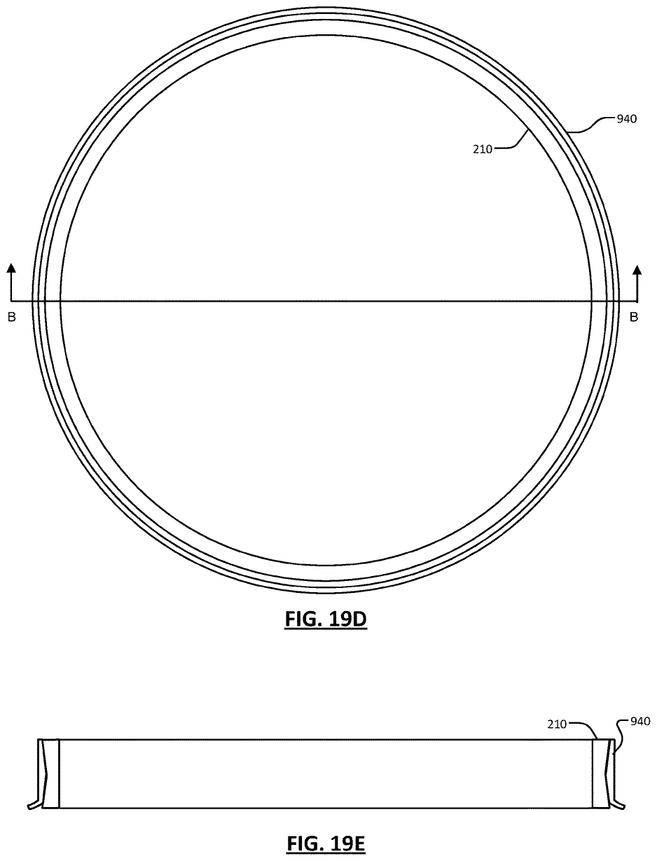

Referring now to FIGS. 19A to 19C, another example of an annular spring-loaded seal band 940 is shown. In FIG. 19A, the annular spring-loaded seal band 940 is in an uncompressed state (when not installed). In FIG. 19B, the annular spring-loaded seal band 940 is in a partial to fully compressed state (when partially installed). In FIG. 19C, the annular spring-loaded seal band 940 is in a fully compressed state with a seal-facing surface 948 thereof abutting a radially outer surface of the seal 210. When in an installed compressed state (e.g., FIG. 19C), in some examples, the inner diameter (inner surface) of the annular spring-loaded seal band 950 does not contact the outer diameter (outer surface) of the seal 210. In some examples, the seal-facing surface 948 of the annular spring-loaded seal band 940 has a contour or shape that mates (or has a complementary contour) with the radially outer surface of the seal 210. For example, the seal-facing surface 948 in FIG. 19A is “V”-shaped.

The annular spring-loaded seal band 940 includes an annular body 942 with a first body portion 943 and an annular arm 944 extending at an angle β₇ from the first body portion 943 when in the uncompressed state in FIG. 19A. A neck 945 is arranged between the annular arm 944 and the first body portion 943. When partially or fully installed as shown in FIGS. 19B and 19C, respectively, the annular arm 944 bends under compression and extends at an angle β_{7*} from the first body portion 943, where β_{7*} is less than β₇. In some examples, β₇ is in a range from 105°to 165°. In some examples, β₇ is in a range from 125°to 155°. In some examples, a difference between β₇ and β_{7*} is in a range from 1° to 25°. In some examples, a difference between β₇ and β₇* is in a range from 3° to 20°.

In some examples, the annular arm 944 does not contact the first body portion 943. In some examples, the annular spring-loaded seal band 940 is installed without a seal 210 if a sufficient plasma seal is created by the annular spring-loaded seal band 940. In some examples when a seal 210 is not used, the annular arm 944 may or may not contact the first body portion 943 when partially or fully installed.

The annular body 942 tapers in opposite directions from a center 949 thereof. The annular spring-loaded seal band 940 has a thickness d8 at the center 949 that is greater than thicknesses at opposite ends of the annular body 942. The annular spring-loaded seal band 940 is configured to bend or deform during installation such that spring force is applied in first and second opposing directions against the surface 238 of the upper plate 112 and the surface 236 of the baseplate 110.

In some examples, the annular spring-loaded seal band 940 has an overall length d11 when not compressed, the annular body 942 has a length d9 and the annular arm 944 has a length d10. In some examples, the length d11 is greater than the length d2 between the lower surface 238 of the upper plate 112 and the upper surface 236 of the baseplate 110. In some examples, d11 is in a range from 102% of d2 to 120% of d 2.

In some examples, the length d10 of the annular arm 944 is in a range from 5%*d11 to 50%*d11. In some examples, the length d10 of the annular arm 944 is in a range from 5%*d11 to 30%*d11. In some examples, a thickness d10* at the end of the annular arm is in a range from d8/1.5 to d8/8. In some examples, a thickness d10* at the end of the annular arm is in a range from d8/2 to d8/6. In some examples, the thickness of the spring-loaded seal cover band tapers from the center to opposite ends thereof.

In some examples, the annular spring-loaded seal band 940 flexes and is at least partially deformed at the neck 945 and at the annular arm 944 without significant plastic deformation when installed. As can be appreciated, dimensions selected in these ranges allow spring force to be tailored to provide sufficient force to block the plasma while staying below spring force that may cause delamination (e.g., less than ⅓ or ½ of the spring force causing delamination in some examples).

FIG. 19D is a top view of the seal 210 and the annular spring-loaded seal band 940 of FIGS. 19B and 19C. As shown in FIG. 19D, the seal 210 and the annular spring-loaded seal band 940 may each have a generally circular shape. Diameters of the seal 210 and the annular spring-loaded seal band 940 may correspond to one another. For example, an inner diameter of the annular spring-loaded seal band 940 may correspond to an outer diameter of the seal 210.

An inner diameter of the seal 210 may correspond to, for example, the radially outer surface 218 of the upper body portion 152 of the baseplate 110. In some example embodiments, the inner diameter of the seal 210 may be slightly smaller than the diameter of the radially outer surface 218, to allow the seal 210 to be stretched around the upper body portion 152 to remain in place.

The inner diameter of the annular spring-loaded seal band 940 may be slightly smaller than the outer diameter of the seal 210, to allow the annular spring-loaded seal band 940 to be stretched around the seal 210 to remain in place. FIG. 19E is a side cross-sectional view of the seal 210 and annular spring-loaded seal band 940 taken at B-B in FIG. 19D.

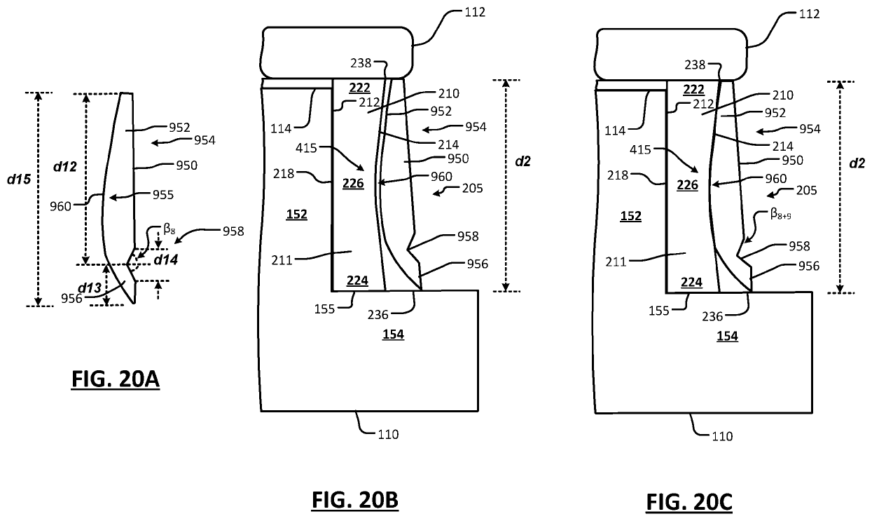

Referring now to FIGS. 20A to 20C, another example of an annular spring-loaded seal band 950 is shown. In FIG. 20A, the annular spring-loaded seal band 950 is in an uncompressed state (when not installed). In FIG. 20B, the annular spring-loaded seal band 950 is in a partially compressed state (when partially installed). In 20C, the annular spring-loaded seal band 950 is in a compressed state (when installed). When in an installed compressed state (e.g., FIG. 20C), in some examples, the inner diameter (inner surface) of the annular spring-loaded seal band 950 does not contact the outer diameter (outer surface) of the seal 210. In some examples, a seal-facing surface 960 of the annular spring-loaded seal band 950 has a contour or shape that mates with or is complementary to a radially outer contour or shape of the seal 210. For example, the seal-facing surface 960 in FIG. 20A has a curved, arcuate, or “D”-shaped contour to match a profile of a radially outer surface of the seal 210.

The annular spring-loaded seal band 950 includes an annular body 954 with a first body portion 952, an annular cavity 958 arranged on a radially outer surface of the annular spring-loaded seal band 950, and an annular arm 956. In some examples, the annular body 954 tapers in opposite directions from a center 955. The annular spring-loaded seal band 950 has a thickness at the center 955 that is greater than a thickness at opposite ends of the annular body 954. The annular spring-loaded seal band 950 is configured to bend such that force is applied in first and second opposing directions against the surface 238 of the upper plate 112 and the surface 236 of the baseplate 110.

In some examples, the annular spring-loaded seal band 950 has an overall length d15, a center of the annular cavity 958 is located a length d12 from one end of the annular body 954 and a length d13 from the opposite end of the annular body 954. The annular cavity 958 is arcuate, curved, or “D”-shaped and extends a length d14 along the radially outer surface. Edges of the annular cavity 958 form first and second angles β₈ and β₉ relative to a horizontal line at a midpoint of the annular cavity 958 when uncompressed in FIG. 20A. In some examples, Bs is greater than B9. In some examples, Bs is less than 39. In other examples, β₈=β₉. In some examples, β₈ and β₉ are in a range from 15° to 75°. In some examples, β₈ and β₉ are in a range from 25° to 55°. In some examples, β₈<β₉(e.g., B₈ is equal to 30° and β₉ is equal to 45°).

When compressed in FIG. 20C, an angular sum of β₈ and β₉ (β₈₊₉ in FIG. 20C) decreases due to compression when installed. In some examples, a difference between the sum of β₈ and β₉ before compression and β₈₊₉ after compression is in a range from 1° to 25°. In other examples, a difference between a sum of β₈ and β₉ before compression and β₈₊₉ after compression is in a range from 3° to 15°. In some examples, the opposite sides of the cavity bend but do not touch when in the compressed state.

In some examples, the annular arm 956 does not contact the annular body 954 when compressed. In some examples, the annular spring-loaded seal band 950 is installed without a seal 210 when a sufficient plasma seal is created by the annular spring-loaded seal band 950. In some examples when a seal 210 is not used, the annular arm 956 may or may not contact the annular body 954 (or opposites sides of the annular cavity 958 come into contact) when the annular spring-loaded seal band 950 compressed during installation.

The length d15, when not compressed, is greater than the length d2 between the lower surface 238 of the upper plate 112 and the upper surface 236 of the baseplate 110. In some examples, d15 is in a range from 102% of d2 to 120% of d2.

In some examples, the length d13 of an annular arm 956 (on a shorter side of the annular body 954) is in a range from 5%*d15 to 50%*d15. In some examples, the length d13 of an annular arm 956 (on a shorter side of the annular body 954) is in a range from 5%*d15 to 30%*d15.

In some examples, the length d14 of the annular cavity 958 is in a range from 5%*d15 to 25%*d15. In some examples, the thickness of the annular spring-loaded seal band 950 tapers from the center 955 to opposite ends thereof. In some examples, the annular spring-loaded seal band 950 bends at the annular cavity 958 and/or at the annular arm 956 without significant plastic deformation. As can be appreciated, dimensions selected in these ranges allow spring force to be tailored to provide sufficient force to block the plasma and stay below spring force that may cause delamination (e.g., less than ⅓ or ½ of the force causing delamination in some examples).

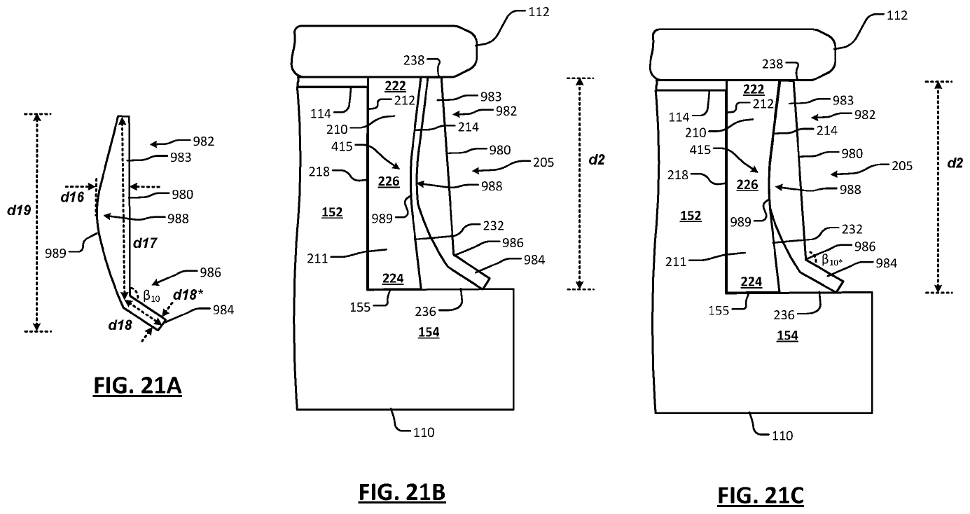

Referring now to FIGS. 21A to 21C, another example of an annular spring-loaded seal band 980 is shown. In FIG. 21A, the annular spring-loaded seal band 980 is in an uncompressed state (when not installed). In FIG. 21B, the annular spring-loaded seal band 980 is in a partially compressed state (when partially installed). In FIG. 21C, the annular spring-loaded seal band 980 is in a compressed state with a seal-facing surface 988 thereof abutting a radially outer surface of the seal 210. When in an installed compressed state (e.g., FIG. 21C), in some examples, the inner diameter (inner surface) of the annular spring-loaded seal band 950 does not contact the outer diameter (outer surface) of the seal 210.In some examples, the seal-facing surface 988 of the annular spring-loaded seal band 980 has a contour or shape that mates (or has a complementary contour) with the radially outer surface of the seal 210. For example, the seal-facing surface 988 in FIG. 21A is “D”-shaped.

The annular spring-loaded seal band 980 includes an annular body 982 with a first body portion 983, and an annular arm 984 extending at an angle β₁₀ from the first body portion 983 when uncompressed in FIG. 21A. When partially or fully installed as shown in FIGS. 21B and 21C, respectively, the annular arm 944 bends under compression and extends at an angle β_{10*} from the first body portion 943, where β_{10*} is less than β_{10.}

In some examples, β₁₀ is in a range from 105° to 165°. In some examples, β₁₀ is in a range from 105° to 165°. In some examples, β₁₀ is in a range from 125° to 155°. In some examples, a difference between β₁₀ and β_{10*} is in a range from 1° to 25°. In some examples, a difference between β₁₀ and β_{10*} is in a range from 3° to 20°. In some examples, the annular arm does not contact the body. In some examples, the annular spring-loaded seal band 980 is installed without a seal 210 if a sufficient plasma seal is created. In some examples when a seal 210 is not used, the annular arm 944 contacts the first body portion when compressed.

A neck portion 986 is arranged between the first body portion 983 and the annular arm 984. The annular body 982 tapers in opposite directions from a center 989 thereof. The annular spring-loaded seal band 980 has a thickness d16 at the center 989. The annular spring-loaded seal band 980 is configured to bend during installation such that spring force is applied in first and second opposing directions against the surface 238 of the upper plate 112 and the surface 236 of the baseplate 110.

In some examples, the annular spring-loaded seal band 980 has an overall length d19 when not compressed, the annular body 982 has a length d17 and the annular arm 984 has a length d18. In some examples, the length d19 is greater than the length d2 between the lower surface 238 of the upper plate 112 and the upper surface 236 of the baseplate 110. In some examples, d19 is in a range from 102% of d2 to 120% of d2.

In some examples, the length d18 of the annular arm 944 is in a range from 5%*d19 to 50%*d19. In some examples, the length d18 of the annular arm 944 is in a range from 5%*d19 to 30%*d19.

In some examples, a thickness d18* at the end of the annular arm 944 is in a range from d16/1.5 to d16/8. In some examples, a thickness d18* at the end of the annular arm is in a range from d16/2 to d16/6. In some examples, the thickness of the spring-loaded seal cover band tapers from the center to opposite ends thereof.

In some examples, the annular spring-loaded seal band 980 flexes and is at least partially deformed at the neck portion 986 and at the annular arm 984 without significant plastic deformation. As can be appreciated, dimensions selected in these ranges allow spring force to be tailored to provide sufficient force to block the plasma and stay below spring force that may cause delamination (e.g., less than ⅓ of the force causing delamination in some examples).

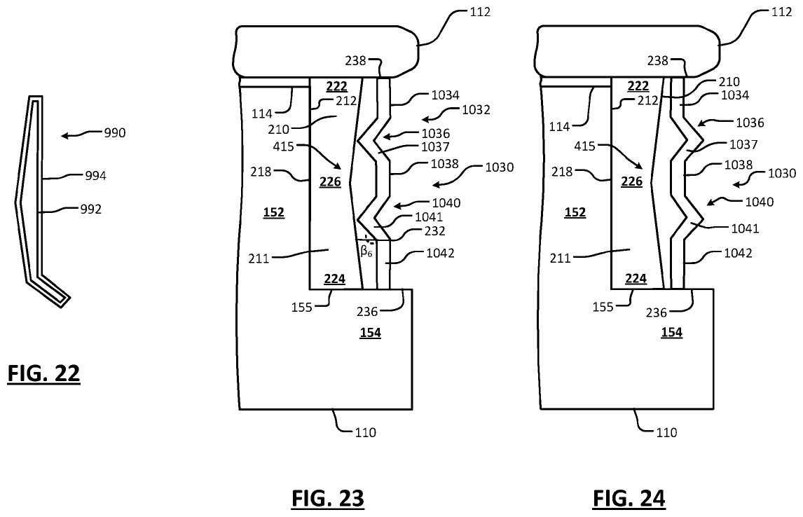

Referring now to FIG. 22, another example of an annular spring-loaded seal band is shown. Some of the examples of the seal bands described herein are made of a single material or group of materials that are machined to desired final surface dimensions. In FIG. 22, an annular spring-loaded seal band 990 includes an annular inner member 992 made of a first type of material. An outer layer 994 is formed on the annular inner member 992 and is made of a second type of material. In some examples, the first type of material of the inner member includes a spring metal such as titanium. In some examples, the outer layer 994 comprises a coated material such as PFA, PTFE, ceramic, or other plasma resistant materials.

In FIGS. 23 and 24, another example of an annular spring-loaded seal band 1030 is shown. The annular spring-loaded seal band 1030 includes an annular body with first, second and third body portions 1034, 1038 and 1042 and first and second “V”-shaped annular body portions 1036 and 1040 connected between the first, second and third body portions 1034, 1038 and 1042, respectively. The “V”-shaped annular body portions 1036 and 1040 form an angle β₆ (or different angles β₆ and β_{6′}) at neck portions located between the first and second “V”-shaped annular body portions 1036 and 1040 and the first, second and third body portions 1034, 1038 and 1042, respectively. The annular spring-loaded seal band 1030 is configured to bend during installation such that sufficient spring force is applied in first and second opposing directions against the lower surface 238 of the upper plate 112 and the upper surface 236 of the baseplate 110. The additional “V”-shaped annular body portion also help to spread plastic deformation over a greater volume. Although not depicted, in some embodiments, the inner diameter surface of the annular spring-loaded seal band 1030 has a contour or shape that mates with or is complementary to a radially outer contour or shape of the seal 210.

The annular spring-loaded seal band 1030 can be installed in different orientations. In FIG. 23, cavities of the “V”-shaped annular body portions 1036 and 1040 extend radially inwardly. In FIG. 24, cavities of the “V”-shaped annular body portions 1036 and 1040 extends radially outwardly.

In some examples, the angle β₆ (or different angles β₆ and β_{6′}) are in a range from 105° to 165°. In some examples, the angle β₆ (or different angles β₆ and β_{6′}) are in a range from 125° to 155°. In some examples, the arms 1037 and 1041 of the “V”-shaped annular body portions 1036 and 1040 are in a range from 5% to 20% of the length of the annular spring-loaded seal band 930.

In FIGS. 23 and 24, another example of an annular spring-loaded seal band 1030 is shown. The annular spring-loaded seal band 1030 includes an annular body with first, second and third body portions 1034, 1038, and 1042. First and second “V”-shaped annular body portions 1036 and 1040 are connected between the first and second body portions 1034 and 1038 and between the second and third body portions 1038 and 1042, respectively. The first and second “V”-shaped annular body portions 1036 and 1040 include arms 1037 and 1041, respectively. In some examples, the first, second and third body portions 1034, 1038, and 1042 extend in a parallel direction and/or along the same line when in an uncompressed state.

The first “V”-shaped annular body portion 1036 forms an angle β₆ (or different angles β₆ and β₆) at neck portions located between the arms 1037 of the first “V”-shaped annular body portion 1036 and the first and second body portions 1034 and 1038. The second “V”-shaped annular body portion 1040 forms an angle β₆ (or different angles β₆ and β₆) at neck portions located between the arms 1041 of the second “V”-shaped annular body portion 1040 and the second and third body portions 1038 and 1042.

The annular spring-loaded seal band 1030 is configured to bend during installation such that sufficient spring force is applied in first and second opposing directions against the lower surface 238 of the upper plate 112 and the upper surface 236 of the baseplate 110. The first and second “V”-shaped annular body portions 1036 and 1040 are configured to spread deformation or plastic deformation that occurs over a wider volume of the annular spring-loaded seal band 1030, which may improve reliability.

The annular spring-loaded seal band 1030 can be installed in different orientations. In FIG. 23, a cavity of the first and second “V”-shaped annular body portions 1036 and 1040 face radially outwardly. In FIG. 24, a cavity of the first and second “V”-shaped annular body portions 1036 and 1040 faces radially inwardly.

In some examples, the angle β₆ (or different angles β₆ and β₆) are in a range from 105° to 165°. In some examples, the angle β₆ (or different angles β₆ and B 6) are in a range from 125° to 155°. In some examples, the legs of the first and second “V”-shaped annular body portions 1036 and 1040 are in a range from 5% to 20% of the length of the annular spring-loaded seal band 1030.

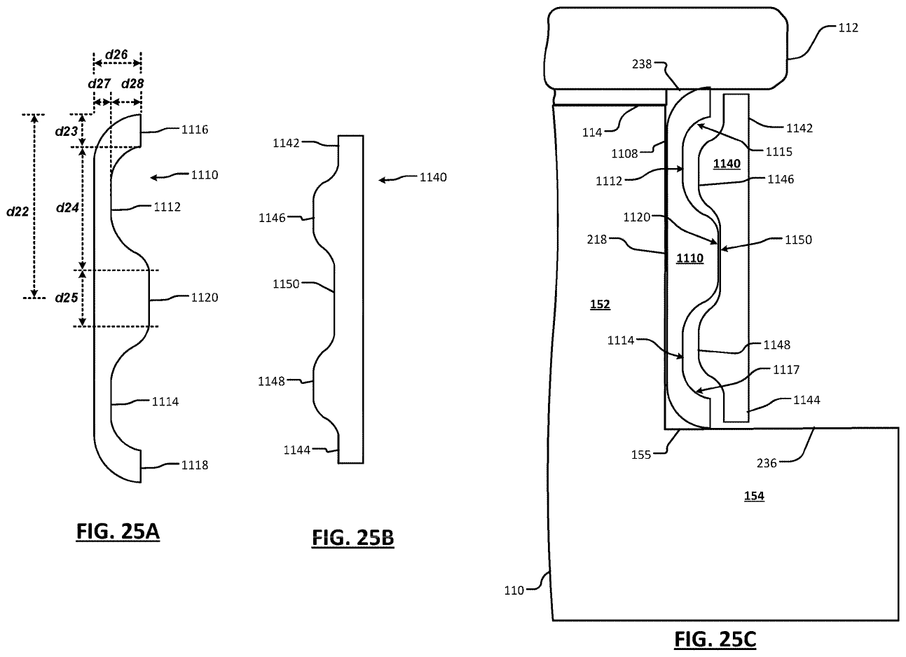

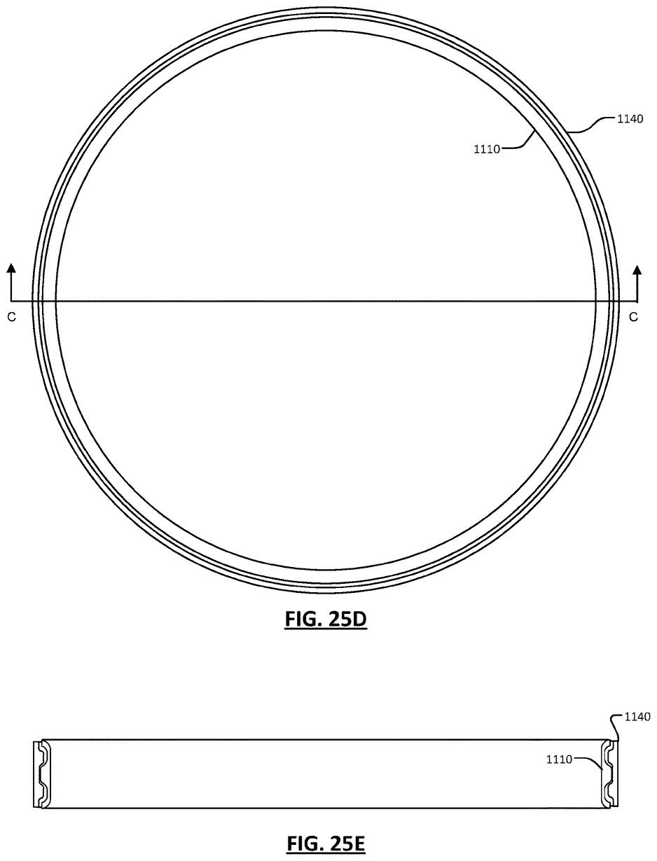

Referring now to FIG. 25A, an annular spring-loaded seal 1110 is shown. The annular spring-loaded seal 1110 includes a first arm 1116 and a second arm 1118. A first spring 1112 is defined between the first arm 1116 and an annular body 1120 of the annular spring-loaded seal 1110. A second spring 1114 is defined between the second arm 1118 and the annular body 1120.

FIG. 25B is a side cross-sectional view of an annular seal cover band 1140 configured to contact the annular spring-loaded seal 1110. The annular seal cover band 1140 includes a first extension 1142, a second extension 1144, and a body portion 1150. A first protrusion 1146 is defined between the first extension 1142 and the body portion 1150, and a second protrusion 1148 is defined between the second extension 1144 and the body portion 1150. In some embodiments, the annular seal cover band 1140 has a cylindrical outer surface that defines the outer diameter of the annular seal cover band 1140. In such embodiments, the cylindrical outer surface can be flat such that the outer diameter is uniform from the top to bottom of the annular seal cover band 1140. In other examples, the outer diameter of the cylindrical outer surface is not uniform from the top to bottom of the annular seal cover band 1140. One or more concave or convex features can be arranged along the cylindrical outer surface.

The inner surface pattern of the annular seal cover band 1140 may correspond to an outer surface shape of the annular spring-loaded seal 1110, to complement one another when the annular spring-loaded seal 1110 and the annular seal cover band 1140 are installed between the upper plate 112 and the upper horizontal surface 155 of the lower body portion 154 of the baseplate 110.

For example, the annular spring-loaded seal 1110 may be placed between the surface 238 of the upper plate 112 and the surface of 236 of the baseplate 110, with a radially inner surface 1108 of the annular spring-loaded seal 1110 contacting the radially outer surface 218 of the upper body portion 152 of the baseplate 110. In some embodiments, the first arm 1116 may press against the surface 238 (e.g., due to the first spring 1112), and the second arm 1118 may press against the surface 236 (e.g., due to the second spring 1114), such that the annular spring-loaded seal 1110 is configured to bend or deform when installed and to bias opposite ends thereof to form a plasma seal.

The annular seal cover band 1140 may be placed around the annular spring-loaded seal 1110, with the first protrusion 1146 extending into a gap left by the first spring 1112, and the second protrusion 1148 extending into a gap left by the second spring 1114. In some examples, the first protrusion 1146 is configured to contact the first spring 1112, and the second protrusion is configured to contact the second spring 1114 when the annular seal cover band 1140 and the annular spring-loaded seal 1110 are installed. The first protrusion 1146 may press against a radius 1115 of the first arm 1116, to improve a level of sealing of the first arm 1116 against the surface 238 of the upper plate 112 (e.g., due to the first protrusion 1146 applying a horizontal force against the radius 1115). Similarly, the second protrusion 1148 may press against a radius 1117 of the second arm 1118, to improve a level of sealing of the second arm 1118 against the surface 236 of the baseplate 110 (e.g., due to the second protrusion 1148 applying a horizontal force against the radius 1117).

In some examples, the first protrusion 1146 and second protrusion 1148 are not configured to contact the respective first spring 1112 and second spring 1114 when the annular seal cover band 1140 and the annular spring-loaded seal 1110 are installed. In some examples, the horizontal width of the first protrusion 1146 and second protrusion 1148 are the same, such that an inner diameter of the annular seal cover band 1140 is defined by both the first protrusion 1146 and second protrusion 1148. Equal protrusion length of 1146 and 1148 reduces the likelihood of the annular seal cover band 1140 rotating counter-clockwise in operation. In some examples, the horizontal width of the first protrusion 1146 and second protrusion 1148 are different, such that only one of the first protrusion 1146 or second protrusion 1148 defines the inner diameter of the annular seal cover band 1140. In some instances, such examples may be preferred when the annular seal cover band 1140 is constructed with materials that are less likely to cause rotation or if it has other features to prevent rotation.

Similar to the first protrusion 1146 and the second protrusion 1148, in various examples the body portion 1150 may or may not contact the annular body 1120 of the annular spring-loaded seal 1110, due to manufacturing tolerances, etc. In some examples, at least one of the protrusions 1146 and 1148 would contact the annular spring loaded seal 1110, but the body portion 1150 does not contact the annular spring-loaded seal 1110.

In some examples, the first protrusion 1146 and the second protrusion 1148 may contact the first spring 1112 and the second spring 1114, respectively. In some examples, the first extension 1142 may contact the first arm 1116 and the second extension 1144 may contact the second arm 1118, respectively.

A height of the annular spring-loaded seal 1110 may be greater than a height of the annular seal cover band 1140. For example, as shown in FIG. 25C, the annular spring-loaded seal 1110 may contact the surface 238 of the upper plate 112 and the surface 236 of the baseplate 110, to compress and form a seal. The annular seal cover band 1140 may not contact the surface 238 of the upper plate 112 and the surface 236 of the baseplate 110, to inhibit or prevent compression of the annular seal cover band 1140.

The annular seal cover band 1140 may protect the annular spring-loaded seal 1110 during substate processing. For example, the annular seal cover band 1140 may be a sacrificial outer PTFE material, to improve a lifetime of the annular spring-loaded seal 1110 (which may also include a PFTE material).

The first spring 1112 and the second spring 1114 may have a mirror arrangement with respect to the annular body 1120, to enable the annular spring-loaded seal 1110 to apply equal pressure to the surface 238 of the upper plate 112 and the surface 236 of the baseplate 110, and avoid rotation of the annular spring-loaded seal 1110. When installed, roughly 60-90% of the inner surface of the annular spring-loaded seal 1110 may directly contact the radially outer surface 218 of the upper body portion 152 of the baseplate 110. The annular seal cover band 1140 may press against the annular spring-loaded seal 1110, in order to improve the spring sealing force of the annular spring-loaded seal 1110.

In some examples, when the annular seal cover band 1140 presses against the annular spring-loaded seal 1110, the first extension 1142 may or may not contact the surface 238 of the upper plate 112, and the second extension 1144 may or may not contact the surface 236 of the baseplate 110. For example, in some implementations the zone of erosion may not extend all the way to the surface 238 (or the surface 236). The zone of concern for high erosion areas may begin at a height below the surface 238, and extend down to around a midpoint of the annular seal cover band 1140. Therefore, there may not be a need for the first extension 1142 to extend all the way to contact the surface 238, or for the second extension 1144 to extend all the way to contact the surface 236, because little or no erosion occurs right at the surface 238 and the surface 236.

Important properties of the annular seal cover band 1140 may include providing a sacrificial layer that can be replaced more easily and more often than the annular spring-loaded seal 1110, while optionally providing additional horizontal force against the radius 1115 and the radius 1117 to improve sealing of the annular spring-loaded seal 1110. If the first extension 1142 and the second extension 1144 are designed to contact the surface 238 and the surface 236, respectively, if manufacturing tolerances, etc. cause the first extension 1142 and the second extension 1144 to have poor mating with the surface 238 and the surface 236 it could lead to tilt of the annular seal cover band 1140 and improper alignment of the annular seal cover band 1140 with the annular spring-loaded seal 1110.

The sealing contact regions (e.g., where the first arm 1116 contacts the surface 238 and the second arm 1118 contacts the surface 236) may be located deep within the groove defined between the surface 236 and the surface 238, to reduce or avoid erosion of the annular spring-loaded seal 1110. Locating the first spring 1112 and the second spring 1114 deep within the groove may also reduce or avoid erosion.

In some examples, the annular spring-loaded seal 1110 has a height of 200% of d22 when not compressed, and a thickness from the radially inner surface 1108 to the end of the first arm 1116 is d26 when not compressed. A height of the end surface of the first arm 1116 is d23, a length of the gap defined by the first spring 1112 is d24, and a height of the annular body 1120 is d25. A thickness of the first spring 1112 is d27, and a distance from a surface of the first spring 1112 to the surface at the end of the first arm 1116 is d28.

In some examples, the thickness d27 of the first spring 1112 may be at least 10% of d26, to allow the first spring to generate enough force to provide a seal at the first arm 1116. The distance d28 may be at least 10% of d26, to allow the first arm 1116 to apply sufficient pressure to the surface 238 and therefore provide proper sealing.

In some examples, the height d23 of the end surface of the first arm 1116 is at least 5% of d22 (or 10% of the total height of the annular spring-loaded seal 1110), and the height d24 of the gap defined by the first spring 1112 is at least 5% of d22 (e.g., at least 10% of the total height of the annular spring-loaded seal 1110). The height d25 of the annular body 1120 is at least 10% of d22 (e.g., at least 20% of the total height of the annular spring-loaded seal 1110).

FIG. 25D is a top view of the annular spring-loaded seal 1110 and the annular seal cover band 1140 of FIGS. 25A-25C. As shown in FIG. 25D, the annular spring-loaded seal 1110 and the annular seal cover band 1140 may each have a generally circular shape. Diameters of the annular spring-loaded seal 1110 and the annular seal cover band 1140 may correspond to one another. For example, an outer diameter of the annular spring-loaded seal 1110 may correspond to an inner diameter of the annular seal cover band 1140.

An inner diameter of the annular spring-loaded seal 1110 may correspond to, for example, the radially outer surface 218 of the upper body portion 152 of the baseplate 110. In some example embodiments, the inner diameter of the annular spring-loaded seal 1110 may be slightly smaller than the diameter of the radially outer surface 218 when not installed, to allow the annular spring-loaded seal 1110 to be stretched around the upper body portion 152 and apply radially inward bias to keep the seal to remain in place. The annular spring-loaded seal 1110 is made with elastic or flexible materials such as PTFE.

The inner diameter of the annular seal cover band 1140 may be slightly smaller than the outer diameter of the annular spring-loaded seal 1110, to allow the annular seal cover band 1140 to be stretched around the annular spring-loaded seal 1110 and apply radially inward bias to keep the cover band 1140 in place. FIG. 25E is a side cross-sectional view of the annular spring-loaded seal 1110 and annular seal cover band 1140 taken at C-C in FIG. 25D.

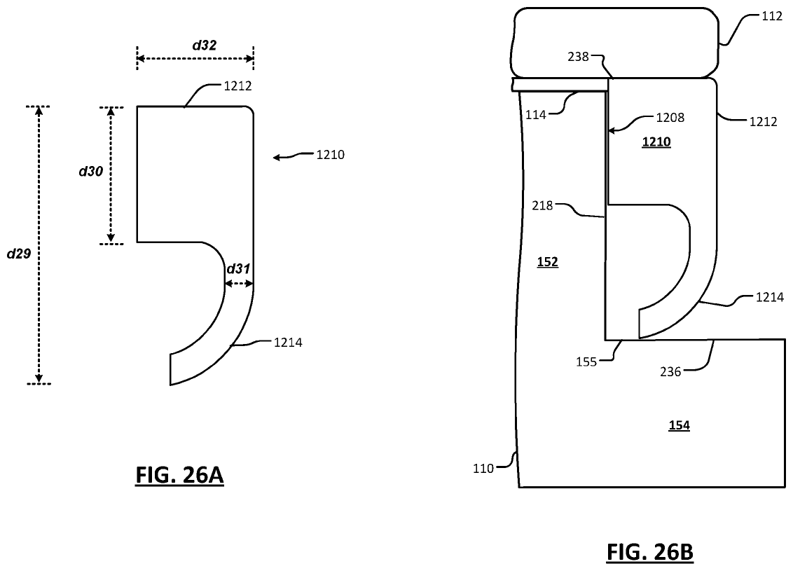

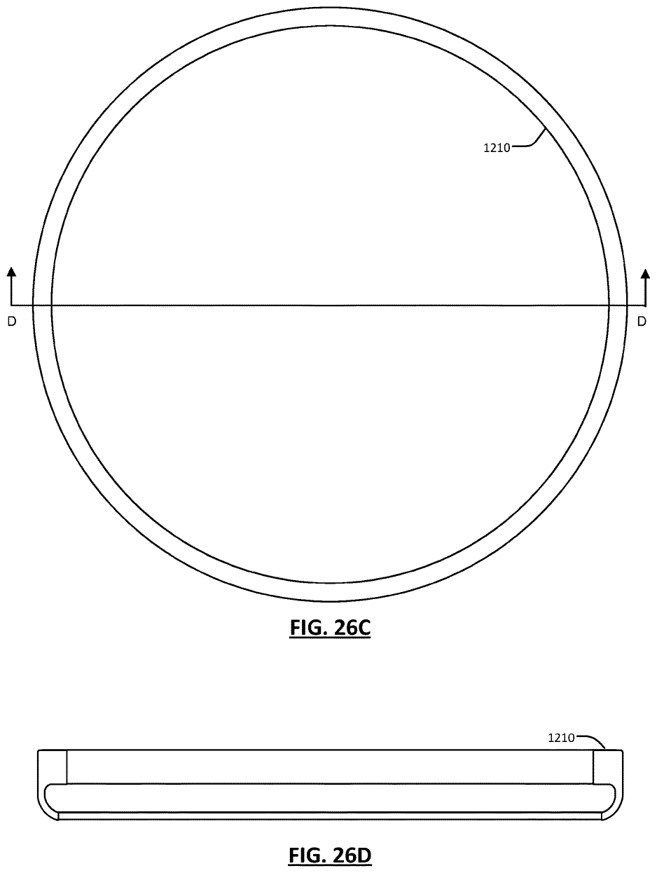

FIG. 26A is a side cross-sectional view of an annular spring-loaded seal 1210, including an annular body 1212 and an annular spring arm 1214. The annular spring arm 1214 extends from the annular body 1212 to bias the annular spring-loaded seal 1210 when the annular spring-loaded seal 1210 is installed in a groove as shown in FIG. 26B.

For example, a radially inner surface 1208 of the annular body 1212 may contact the radially outer surface 218 of the upper body portion 152 of the baseplate 110, and an upper surface of the annular body 1212 may contact the surface 238 of the upper plate 112. The annular spring arm 1214 contacts the surface 236 of the baseplate 110. In some embodiments, the annular spring arm 1214 has a substantially uniform thickness. In some embodiments, the annular spring arm 1214 has a larger thickness closer to the annular body 1212 and a smaller thickness closer to the distal end of the annular spring arm 1214. In some embodiments, the annular spring arm 1214 has a larger thickness at the distal end of the annular spring arm 1214 compared to a region with a smaller thickness closer to the annular body 1212.

The annular spring-loaded seal 1210 is configured to bend or deform when installed, and to bias the annular spring arm 1214 and the upper surface of the annular body 1212 to form a plasma seal. When installed, the annular spring arm 1214 biases downward and away from the radially outer surface 218. The annular spring arm 1214 may inhibit or prevent rotation of the annular spring-loaded seal 1210.

For example, the annular spring-loaded seal 1210 may have a tendency to rotate clockwise in FIG. 26B, where a right side edge of the top of the annular spring-loaded seal 1210 moves down away from the surface 238 of the upper plate 112. A majority of sealing provide by the annular spring-loaded seal 1210 may occur near an upper left corner of the annular spring-loaded seal 1210 in FIG. 26B. When the annular spring-loaded seal 1210 comprises a material that is more like metal and less like an elastomer, it may be desirable to have a high force to conform the annular spring-loaded seal 1210 to the surface 238 of the groove. It is also desirable to have a higher area of surface contact in order to improve sealing. Downward rotation of the annular spring-loaded seal 1210 reduces the force applied at the top of the annular spring-loaded seal 1210 to the surface 238, and also reduces an area of contact between the top of the annular spring-loaded seal 1210 and the surface 238.

The annular spring-loaded seal 1210 may naturally rotate due to mechanical properties of the annular spring-loaded seal 1210 when stretched and installed in the groove, and the annular spring arm 1214 counteracts rotation by providing an upward force to inhibit the annular spring-loaded seal 1210 from rotating clockwise. The annular spring arm 1214 is designed to apply a desired direction of force to counter the rotation, and depending on the shape of the body of the annular body 1212 of the annular spring-loaded seal 1210, various shapes of the annular spring arm 1214 may be more or less effective at countering rotation. Therefore, specific dimensions of the annular spring arm 1214 may be selected to optimize a direction and amount of force to counteract rotation. Generally, all embodiments of the disclosed seals and cover bands are designed to reduce tendency of rotation while improving useful lifetime. These seals are designed to withstand extreme wafer fabrication conditions for many RF hours. When the seals are eroded to an extent, they will need to be replaced. The novel shape and geometry of the disclosed seals not only allow the seals to counteract rotation (after multiple cycles of extreme temperature/pressure changes) but also to ensure that enough material is packed around the plasma attack region to prolong their useful life.

Although FIGS. 26A and 26B illustrate the annular spring arm 1214 as curving inward past a halfway point of the annular body 1212, in other examples the annular spring arm 1214 may have other shapes. For example, the annular spring arm 1214 may curve in an opposite direction, may extend further than the example illustrated in FIGS. 26A and 26B, may have a sharper or more gradual curve, may extend from an opposite side of the annular body 1212, etc. When the annular spring arm 1214 extends from the opposite side of the annular body 1212, the annular spring arm 1214 may be biased downwards and towards the radially outer surface 218.

In some examples, the annular spring-loaded seal 1210 has a height d29 when not compressed, the annular body 1212 has a height d30 and a width d32, and the annular spring arm 1214 has a width d31. In some examples, the height d30 is at least 10% of d29, and the width d31 is at least 5% of d32.

FIG. 26C is a top view of the annular spring-loaded seal 1210 of FIGS. 26A and 26B. As shown in FIG. 26C, the annular spring-loaded seal 1210 may have a generally circular shape. An inner diameter of the annular spring-loaded seal 1210 may correspond to, for example, the radially outer surface 218 of the upper body portion 152 of the baseplate 110.

In some example embodiments, the inner diameter of the annular spring-loaded seal 1210 may be slightly smaller than the diameter of the radially outer surface 218, to allow the annular spring-loaded seal 1210 to be stretched around the upper body portion 152 to remain in place. FIG. 26D is a side cross-sectional view of the annular spring-loaded seal band 1310 taken at D-D in FIG. 26C.

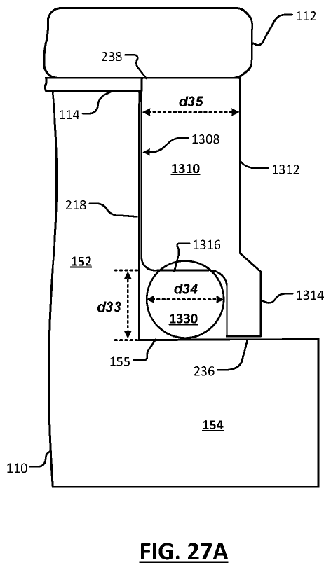

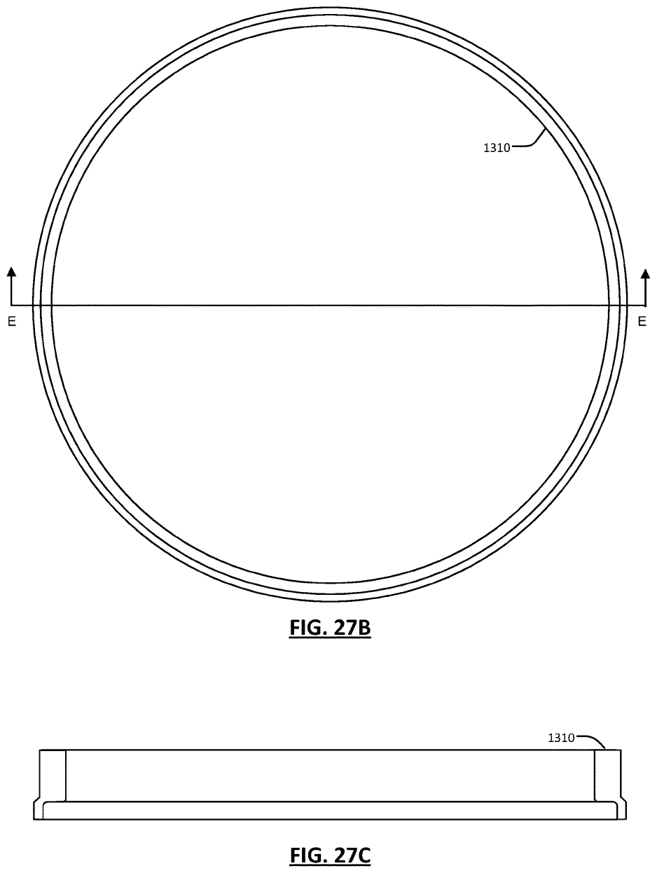

Referring now to FIG. 27A, an annular spring-loaded seal band 1310 that can be used with an O-ring seal 1330 is shown. The annular spring-loaded seal band 1310 includes an annular body with a radially inner surface 1308, a radially outer surface 1312, and a projection 1314. The projection 1314 may define a pocket region for the O-ring seal 1330 and/or provide mechanical stiffness to the annular spring-loaded seal band 1310. In this example, the O-ring seal 1330 may press straight up against the annular spring-loaded seal band 1310 to provide a sealing force, thereby avoiding rotation of the annular spring-loaded seal band 1310.

For example, the radially inner surface 1308 of the annular spring-loaded seal band 1310 contacts the radially outer surface 218 of the upper body portion 152 of the baseplate 110, an upper surface of the annular spring-loaded seal band 1310 contacts the surface 238 of the upper plate 112, and the lower surface of the projection 1314 contacts the surface 236 of the baseplate 110. The annular spring-loaded seal band 1310 is configured to bend or deform when installed and to bias opposite ends thereof against the surface 238 of the upper plate 112 and the surface 236 of the baseplate 110, respectively, to form a plasma seal.

The O-ring seal 1330 is located in the pocket region of the annular spring-loaded seal band 1310, between the lower surface 1316 of the annular body of the annular spring-loaded seal band 1310, and the surface 236 of the baseplate 110, and between the projection 1314 of the annular spring-loaded seal band 1310 and the radially outer surface 218 of the upper body portion 152 of the baseplate 110.

In some examples, the annular spring-loaded seal band 1310 is rotated slightly clockwise when installed to apply pressure on sealing locations of the annular spring-loaded seal band 1310 and/or the O-ring seal 1330. In some examples, various portions of the annular spring-loaded seal band 1310 may provide a vacuum seal or a redundant seal to protect the bonding layer 114 and the O-ring seal 1330. In some examples, the O-ring seal 1330 may be made of or include an outer coating of PFA or PTFE (e.g., an elastomer).

The projection 1314 defines a pocket region around the O-ring seal 1330. The pocked region is sized to allow enough room for the O-ring seal 1330 to be located therein and to bias the O-ring seal 1330 inwardly. In other words, the projection 1314 of the annular spring-loaded seal band 1310 restricts movement of the O-ring seal 1330. The projection 1314 and the lower surface 1316 are sufficiently rigid to provide a sealing surface that is parallel to and biased against the lower surface 236 of the baseplate 110, and to reduce the likelihood of plasma making it past the annular spring-loaded seal band 1310 and entering the pocket region.

The projection 1314 has a radial thickness that is sufficiently wide to provide mechanical stiffness and support required for the annular spring-loaded seal band 1310, which reduces the likelihood of plasma entering the pocket region. Although FIG. 27A illustrates the projection 1314 as including a neck portion across from the lower surface 1316, in other examples the projection 1314 may have other shapes, such as a continuous surface extension of the outer surface 1312 of the annular body of the annular spring-loaded seal band 1310.

In some examples, the annular body of the annular spring-loaded seal band 1310 has a width d35 when not compressed, the projection 1314 has a length d33 from the lower surface 1316 to an end of the projection 1314 when the projection 1314 is not compressed, and the O-ring seal 1330 has a diameter d34.

In some examples, d33 is in a range from 50% of d 34 to 95% of d34. This allows the annular spring-loaded seal band 1310 to provide compression on the O-ring seal 1330 when the annular spring-loaded seal band 1310 and the O-ring seal 1330 are installed. In some examples, d34 is less than or equal to 125% of d35. This allows the O-ring seal 1330 to provide pressure against the annular spring-loaded seal, to maintain sealing functionality of surfaces of the annular spring-loaded seal band 1310 when the annular spring-loaded seal band 1310 and the O-ring seal 1330 are installed.

With additional protection provided by the seal cover band, the lifetime of the seal can be prolonged so that failure of the seal does not control MTBC for applications such as conductor etch (CE). Instead of replacing the seal at every MTBC period, the seal can be used for several MTBC periods in many dielectric etch (DE) applications where erosion of the seal is minimal. This change leads to a reduction in cost and an increase in tool productivity.

The seal cover band also provides additional mechanical support to seals made of softer materials and mitigates buckling risk. This allows the use of seals with higher aspect ratios (corresponding to a height of the seal divided by a thickness of the seal). Higher aspect ratio seals are required for ESCs used in some applications such as next generation DE.

FIG. 27B is a top view of the annular spring-loaded seal band 1310 of FIG. 27A. As shown in FIG. 27B, the annular spring-loaded seal band 1310 may have a generally circular shape. An inner diameter of the annular spring-loaded seal band 1310 may correspond to, for example, the radially outer surface 218 of the upper body portion 152 of the baseplate 110.

In some example embodiments, the inner diameter of the annular spring-loaded seal band 1310 may be slightly smaller than the diameter of the radially outer surface 218, to allow the annular spring-loaded seal band 1310 to be stretched around the upper body portion 152 to remain in place. FIG. 27C is a side cross-sectional view of the annular spring-loaded seal band 1310 taken at E-E in FIG. 27B.

FIGS. 3-18 illustrate various spring/bending mechanisms of the seals and cover bands in a direct representation format. FIGS. 19-21 and 25-27 illustrate embodiments of spring/bending mechanisms enclosed or integrated into examples of seals and cover bands.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

1-29. (canceled)

30. A spring-loaded seal band for protecting a bonding layer of a substrate support, the spring-loaded seal band comprising:
an annular body having a first length when the spring-loaded seal band is in an uncompressed state, the annular body comprises:
a first annular body portion;
an annular arm; and
a flexible neck portion that connects the first annular body portion and the annular arm,
wherein the spring-loaded seal band is configured to surround the substrate support between a lower surface of a top plate and an upper surface of a baseplate, the lower surface of the top plate and the upper surface of the baseplate is separated by a second length,
wherein the first length is greater than the second length, and
wherein the flexible neck portion is configured to bend when the spring-loaded seal band is in an installed compressed state and biased against the upper surface of the baseplate and the lower surface of the top plate, and the first length is reduced when the spring-loaded seal band is in the installed compressed state.

31. The spring-loaded seal band of claim 30, wherein the annular body includes a material selected from a group consisting of perfluoroalkoxy alkanes (PFA) and polytetrafluoroethylene (PTFE).

32. The spring-loaded seal band of claim 30, wherein the first length is 1.02 times to 1.2 times greater than the second length when in the uncompressed state.

33. The spring-loaded seal band of claim 30, wherein the annular arm extends from the first annular body portion at an angle in range from 105° to 165° when in the uncompressed state.

34. The spring-loaded seal band of claim 30, wherein the annular arm extends from the first annular body portion at an angle from 125° to 155° when uncompressed.

35. The spring-loaded seal band of claim 30, wherein the annular arm has a length in a range from 5% to 50% of the first length.

36. The spring-loaded seal band of claim 30, wherein the annular arm has a length in a range from 5% to 30% of the first length.

37. The spring-loaded seal band of claim 30, wherein:
the spring-loaded seal band includes an annular inner member and an outer layer on the annular inner member,
wherein the outer layer comprises a plasma-resistant material.

38. The spring-loaded seal band of claim 37, wherein:
the annular inner member includes spring metal, and
the outer layer is selected from a group consisting of perfluoroalkoxy alkanes (PFA), polytetrafluoroethylene (PTFE), and ceramic.

39. The spring-loaded seal band of claim 30, wherein a seal-facing surface of the first annular body portion has a shape selected from a group consisting of “V”-shaped and “D”-shaped.

40. The spring-loaded seal band of claim 33, wherein the angle decreases in a range from 1° to 25° when in the installed compressed state.

41. The spring-loaded seal band of claim 33, wherein the angle decreases in a range from 3° to 15° when in the installed compressed state.

42. A spring-loaded seal band for protecting a bonding layer a substrate support, comprising:
an annular body having a first length when the spring-loaded seal band is in an uncompressed state, the annular body comprises:
a first annular body portion;
an annular arm; and
a “V”-shaped cavity between the first annular body portion and the annular arm,
wherein the spring-loaded seal band is configured to surround the substrate support between a lower surface of a plate and an upper surface of a baseplate, the lower surface of the plate and the upper surface of the baseplate is separated by a second length,
wherein the first length is greater than a second length, and
wherein at least one of the first annular body portion and the annular arm of the spring-loaded seal band is configured to bend when in an installed compressed state to bias the spring-loaded seal band against the upper surface of the baseplate and the lower surface of the plate and the first length is reduced when the spring-loaded seal band is in the installed compressed state.

43. The spring-loaded seal band of claim 42, wherein the annular body includes a material selected from a group consisting of perfluoroalkoxy alkanes (PFA) and polytetrafluoroethylene (PTFE).

44. The spring-loaded seal band of claim 42, wherein the first length is in a predetermined range from 1.02 to 1.2 times the second length.

45. The spring-loaded seal band of claim 42, wherein a middle of the “V”-shaped cavity is located in a range from 5% to 50% of a length of the spring-loaded seal band.

46. The spring-loaded seal band of claim 42, wherein a middle of the “V”-shaped cavity is located in a range from 5% to 30% of a length of the spring-loaded seal band.

47. The spring-loaded seal band of claim 42, wherein sides of the “V”-shaped cavity form a first angle and a second angle relative to a middle of the “V”-shaped cavity, wherein the first angle and the second angle are in a range from 25° to 55°.

48. The spring-loaded seal band of claim 42, wherein the annular arm has a length in a range from 5% to 50% of the first length.

49. The spring-loaded seal band of claim 42, wherein the annular arm has a length in a range from 5% to 30% of the first length.

50. The spring-loaded seal band of claim 42, wherein:
the spring-loaded seal band includes an annular inner member and an outer layer on the annular inner member, the outer layer comprises a plasma-resistant material,
the annular inner member includes spring metal, and
the outer layer is selected from a group consisting of perfluoroalkoxy alkanes (PFA), polytetrafluoroethylene (PTFE), and ceramic.

51. The spring-loaded seal band of claim 42, wherein a seal-facing surface of the first annular body portion has a shape selected from a group consisting of “V”-shaped and “D”-shaped.

52. The spring-loaded seal band of claim 47, wherein a sum of the first angle and the second angle decreases in a range from 1° to 25° when in the installed compressed state.

53. The spring-loaded seal band of claim 47, wherein a sum of the first angle and the second angle decreases in a range from 3° to 15° when in the installed compressed state.

54-72. (canceled)
